(19) United States
(12) Patent Application Publication
(10) Pub. No.: US 2024/0276675 A1
(43) Pub. Date: Aug. 15, 2024

(54) METHODS AND APPARATUS TO MITIGATE HOTSPOTS IN INTEGRATED CIRCUIT PACKAGES USING GIMBALING NOZZLES AND JET VECTORING IMPINGEMENT

(71) Applicant: Intel Corporation, Santa Clara, CA (US)

(72) Inventors: Prabhakar Subrahmanyam, San Jose, CA (US); Vishnu Prasadh Sugumar, Santa Clara, CA (US); Patrick L. Connor, Beaverton, OR (US); Ying Feng Pang, San Jose, CA (US); Mark Lawrence Bianco, Mountain View, CA (US)

(21) Appl. No.: 18/605,305

(22) Filed: Mar. 14, 2024

(51) Int. Cl. H05K 7/20; B05B 1/16; B05B 15/68; B05B 15/70; G06F 1/20

(52) U.S. Cl. CPC H05K 7/20272; B05B 1/16; B05B 15/68; B05B 15/70; G06F 1/20; H05K 7/20281

(57) ABSTRACT

Systems, apparatus, articles of manufacture, and methods to mitigate hotspots in integrated circuit packages using gimballing nozzles and jet vectoring impingement are disclosed. An apparatus includes an array of nozzles to direct a cooling fluid toward an integrated circuit package. The array of nozzles includes a first nozzle and a second nozzle. The apparatus further includes a plate to carry the array of nozzles. The first nozzle is selectively moveable relative to the integrated circuit package and relative to the second nozzle. Movement of the first nozzle relative to the integrated circuit package including rotational movement and translational movement.

### FIELD OF THE DISCLOSURE

This disclosure relates generally to cooling systems and, more particularly, to methods and apparatus to mitigate hotspots in integrated circuit packages using gimbaling nozzles and jet vectoring impingement.

### BACKGROUND

Electronic components, such as microprocessors and integrated circuit packages, generally produce heat during operation. Excessive heat may degrade the performance, reliability, and/or life expectancy of such electronic components and may even cause component failure. Accordingly, in many instances, cooling systems are implemented to dissipate heat from such electronic components to maintain the operational temperature of such components within a suitable range.

### BRIEF DESCRIPTION OF THE DRAWINGS

FIG. 1 illustrates one or more example environments in which teachings of this disclosure may be implemented.

FIG. 2 illustrates an example jet impingement cooling system constructed in accordance with teachings disclosed herein with an example array of nozzles that can be independently moved relative to one another and relative to an example IC package.

FIG. 3 illustrates the example jet impingement cooling system of FIG. 3 with some of the example nozzles moved to different positions.

FIG. 4 illustrates an example layout of an example IC package based on a single monolithic semiconductor die on which simulations have been performed to show improvements in temperature control achieved through the implementation of teachings disclosed herein.

FIG. 5 illustrates an example temperature profile resulting from a simulation of the IC package of FIG. 4 based on nozzles arranged in orthogonal positions.

FIG. 6 illustrates an example temperature profile resulting from a simulation of the IC package of FIG. 4 based on nozzles dynamically adjusted in accordance with teachings disclosed herein.

FIG. 7 illustrates an example temperature profile resulting from a simulation of an example multi-chip IC package based on nozzles arranged in orthogonal positions.

FIG. 8 illustrates a top view of an example physical arrangement of example nozzles supported by a nozzle plate over top of the IC package of FIG. 7.

FIG. 9 illustrates an example temperature profile resulting from a simulation of the multi-chip IC package of FIG. 7 based on nozzles dynamically adjusted in accordance with teachings disclosed herein.

FIG. 10 illustrates the top view of the example nozzles of FIG. 8, but with the nozzles adjusted in accordance with the simulation of FIG. 9.

FIG. 11 is an exploded view of an example jet impingement cooling system constructed in accordance with teachings disclosed herein.

FIG. 12A is an upward facing perspective view of the example nozzle enclosure of FIG. 11.

FIG. 12B is a downward facing perspective view of the example nozzle enclosure of FIG. 11.

FIGS. 13A and 13B correspond to the perspective views of FIGS. 12A and 12B, respectively, with some of the example nozzles raised toward the example nozzle plate in accordance with teachings disclosed herein.

FIG. 14A is a cross-sectional side view of the example nozzle enclosure of FIGS. 11-13B.

FIG. 14B is a top view of the example nozzle enclosure of FIGS. 11-13B cutaway along a plane passing through enclosure to show an example arrangement of channels disposed therein.

FIG. 15 is a top view of the example actuator plate of FIG. 11.

FIG. 16 is an enlarged view of a portion of the example nozzle plate assembly of FIGS. 11-15.

FIG. 17 is a cross-sectional view of an example nozzle contained within an example nozzle casing.

FIG. 18 is a cross-sectional view of the example nozzle of FIG. 17 moved to a different position relative to the example nozzle casing.

FIG. 19 is a cross-sectional view of another example nozzle contained within another example nozzle casing.

FIG. 20 is a cross-sectional view of the example nozzle of FIG. 19 moved to a different position relative to the example nozzle casing.

FIGS. 21-24 are three-dimensional renderings of an example nozzle oriented in different directions within an example nozzle casing.

FIG. 25 illustrates the example array of nozzles within the housing of FIG. 11 with the nozzle seat assemblies removed and the housing represented as see-through for the sake of visibility of the internal components (e.g., the nozzles).

FIG. 26 is a block diagram of an example implementation of the example controller circuitry FIG. 2 and/or 11.

FIGS. 27 and 28 are flowcharts representative of example machine readable instructions and/or example operations that may be executed, instantiated, and/or performed by example programmable circuitry to implement the controller circuitry of FIG. 26.

FIG. 29 is a block diagram of an example processing platform including programmable circuitry structured to execute, instantiate, and/or perform the example machine readable instructions and/or perform the example operations of FIGS. 27 and 28 to implement the controller circuitry of FIG. 26.

FIG. 30 is a block diagram of an example implementation of the programmable circuitry of FIG. 29.

FIG. 31 is a block diagram of another example implementation of the programmable circuitry of FIG. 29.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Integrated circuit (IC) packages and/or semiconductor dies with high power density silicon generate relatively high heat loads. Moreover, the silicon often has a non-uniform power distribution with different areas of the silicon using different amounts of power and, thus, generating different amounts of heat. For instance, in multi-chip modules (MCM), different dies (also known as chips, chiplets, or tiles) may perform different functions and/or be operated independent of one another to produce differing amounts of heat due to the distributed nature of power being dissipated. This non-uniform power distribution happens due to different workloads performed by the different dies. Similarly, in a monolithic system on chip (SoC) different regions of the semiconductor die can include different circuitry with different functions and/or that perform different tasks at different times based on different workloads that result in a non-uniform power distribution and, thus, a non-uniform temperature profile. Thermal challenges continue to increase as semiconductor technology advances because integrated circuits continue to decrease in size (e.g., reduce overall die silicon footprint) while also increasing in power (regardless of changes in die silicon footprint) because of decreases in the size and associated density of transistors used in integrated circuits. Further, market demands and associated advances in technology are leading to dies that are thinner than in the past, which exacerbates the challenges of adequately cooling such dies while in operation.

Different areas on an IC package (e.g., different areas within a monolithic SoC or different dies within an MCM) dissipate different amounts of power at different times, which can result in hotspots. In some examples, as used herein, a hotspot on an IC package is a location on the package that is producing more heat than other locations on the package. That is, in some examples, a hotspot is defined based on a temperature differential between the location of the hotspot and other locations and not necessarily the actual measured temperature of the hotspot or the other locations. Thus, in some examples, an entire IC package may be relatively cool, but a certain location is at a relatively higher temperature than other locations so as to qualify as a hotspot. In some examples, a location is identified as a hotspot only when a temperature differential between the location and other locations satisfies (e.g., exceeds) a differential temperature threshold. In some examples, as used herein, a hotspot refers to a location on an IC package with a temperature that satisfies (e.g., exceeds) a temperature threshold regardless of the temperature of other locations on the package. In some examples, a hotspot refers to a location on an IC package with a temperature that both satisfies (e.g., exceeds) a temperature threshold and that results in a temperature differential relative to other locations on the package that satisfies (e.g., exceeds) a temperature differential threshold. Thus, a hotspot may be defined in terms of absolute (e.g., measured) temperatures at specific locations of an IC package and/or in terms of temperature gradients (e.g., temperature differentials) across the IC package.

One approach to dissipate heat produced by packages and mitigate against hotspots includes a jet impingement cooling system with an array of nozzles positioned at fixed locations relative to the package to impinge cooling fluid on corresponding dies and/or on corresponding areas of the non-uniform package. Direct jet impingement on the surface of a bare die silicon delivers more ability to remove heat than other cooling techniques because of the higher heat transfer coefficients that impinging jets can deliver. By selectively turning off or on different ones of the nozzles (and/or adjusting the relative fluid flow through different ones of the nozzles), the delivery of the cooling fluid impinging on the package can focus on high temperature areas. However, such cooling systems include several limitations. Firstly, the amount of fluid flow that can be delivered through any given nozzle is limited and, as a result, may be insufficient to adequately cool a particular hotspot. Secondly, the system is inefficient because some of the nozzles may be positioned over regions of the package that are not that hot such that the nozzles are not needed at a given point in time and, thus, are underutilized. More particularly, in a package with a non-uniform die power distribution, power tends to be concentrated in certain areas that drive higher Tⱼ-rise (junction temperature rise) resulting in localized hotspots on areas of the die where the power is higher. The lower power areas of the die do not produce hotspots and impinging jets of cooling fluid on such areas does not significantly contribute to an overall reduction in junction temperature across the entirety of the die. Thus, the jets produced by the associated nozzles are effectively wasted because they are impinging on a lower power (e.g., colder) area of the non-uniformly powered package. Finally, existing implementations of jet impingement cooling systems are limited to responding to hotspots that have already arisen in the package. That is, such cooling systems are merely reactive to present circumstances rather than able to preemptively or proactively cool a package in a targeted manner to reduce hotspots from arising in the first place.

Examples disclosed herein overcome the above limitations of existing jet impingement cooling systems by enabling nozzles in an array of nozzles to be dynamically gimballed or angled in different directions to provide cooling fluid at any suitable location on an IC package in response to current temperature measurements of the IC package. Thus, in some examples, multiple nozzles can be oriented to direct cooling fluid to the same location (or relatively nearby locations), thereby increasing the cooling capacity to address critical (e.g., high temperature) hotspots (e.g., approaching, at, or exceeding Tⱼₘₐₓ specified for the package). Furthermore, if a particular nozzle is orthogonally aligned with a region of an IC package that is not currently generating a significant amount of heat (and/or is not associated with high power dissipation), the nozzle can be used to cool some other area on the IC package that is at a higher temperature, though less than a critical temperature, thereby helping to prevent the other area from reaching a critical temperature. Thus, in addition to reducing the temperature and/or occurrence of localized hotspots, thereby reducing the junction temperature of a package (or a particular portion of the package), examples disclosed herein also reduce the spread of the temperature gradient across the surface of the package so that the temperature across the package becomes more even. That is, examples disclosed herein reduce the overall range of temperatures (e.g., differential between highest and lowest temperatures) experienced across the entire body of the IC package. Reducing the junction temperature and the temperature gradient of an IC package can increase the reliability and longevity or useful life of the package.

Additionally, in some examples, the angle or orientation of nozzles is controlled based on a priori knowledge of workloads and/or tasks to be performed by different areas (e.g., different dies, different circuity) of an IC package. That is, a priori knowledge of workloads and/or tasks to be performed by different blocks of circuitry within an IC package enables a controller to determine the areas of the package that are bound to generate heat in the near future to give rise to future hotspots if mitigating action to cool such areas is not taken. Accordingly, in some examples, the nozzles are directed towards areas expected to heat up based on an increase in power dissipation to begin cooling the areas before the power dissipation increases. In this manner, the areas associated with future hotspots (e.g., predicted hotspots, potential hotspots) are preemptively cooled to reduce and/or prevent Tⱼ spikes associated with those areas. In some examples, this preemptive cooling process prevents the associated area of the package from becoming an actual hotspot.

In some examples, future hotspots that are preemptively cooled in accordance with teachings disclosed herein are imminent in nature with the workloads beginning to dissipate power within a few milliseconds to a few seconds after the system becomes aware of the workloads. However, despite this relatively short window to respond to such information, experimental testing based on computational fluid dynamic (CFD) simulations has shown that the preemptive cooling techniques with gimballed nozzles disclosed herein can achieve as much as a 10° C. reduction in the rise of Tⱼ relative to known cooling systems that are limited to reacting to hotspots after the fact and/or are limited to fixed position nozzles.

For purposes of clarity, as noted above and used herein, hotspots can refer to actual hotspots (e.g., current hotspots) and future hotspots (e.g., predicted hotspots, potential hotspots). Actual or current hotspots refers to hotspots that can be detected or measured (e.g., with one or more temperature sensors). That is, actual hotspots are a function of the actual temperature of the package at a given point in time and, thus, correspond to the current operation and associated thermal profile of an associated package. By contrast, future, predicted, or potential hotspots are hotspots that have not yet been realized but are likely to become actual hotspots based on expected and/or anticipated operations of an associated package absent any changes to present (current) operations of an associated cooling system. That is, the actual (e.g., measured) temperature of a future hotspot may not yet satisfy a temperature threshold and/or a temperature differential threshold to qualify for an actual hotspot. However, in the absence of changes to the operation of a cooling system and/or changes in the operation of the IC package, the temperature of the future hotspot is expected to rise until it meets the criteria (e.g., satisfies the threshold(s)) to constitute an actual hotspot as defined above.

In some examples, not only are nozzles capable of rotational movement relative to an IC package, but the nozzles are also capable of translational movement relative to an IC package. More particularly, in some examples individual nozzles can be selectively raised or lowered to different heights relative to the IC package, thereby adjusting the nature of the jet stream impinging on the surface of the IC package. This vertical translational movement can facilitate the targeting of particular areas on the IC package and can also affect cross flow resulting from the impinging jet stream, which can impact the heat transfer efficiency of adjacent jet streams from adjacent nozzles.

Not only do examples disclosed herein improve the efficiency of cooling systems for individual IC packages, teachings disclosed herein also provide improvements to the operation of data centers more generally. Specifically, the server utilization rates of data centers can vary widely depending on the purpose, design, and management of the facility. However, it is not uncommon for many data centers to operate at a server utilization rate far below 100%. In some cases, the nominal utilization can be as low as 20% due to overprovisioning for peak demand, redundancy, and the need for reliability and availability. As such, the data center's cooling system will also tend to be designed for peak loads and underutilized for much of its lifetime. However, the dynamic cooling techniques of examples disclosed herein can help reduce the amount for which a data center must be overprovisioned to meet peak demands because the dynamic capacity of any given core and/or package may be increased while maintained at acceptable operating temperatures due to the improved cooling techniques disclosed herein.

Data center costs are a combination of many factors including the physical hardware and installation costs required to build the data center, and the ongoing resource consumption such as electricity and cooling required to run the data center. This can be further broken into resources dedicated to running specific workloads and those diverted to the idle power consumption of the data center. However, garnering more performance per core, and/or more performance per package, by implementing teachings disclosed herein, may enable a reduction in the size of a data center to meet a given peak workload of its performance envelope. This may reduce both construction costs as well as operating costs associated with maintaining and running additional hardware which is generally underutilized except for peak workloads.

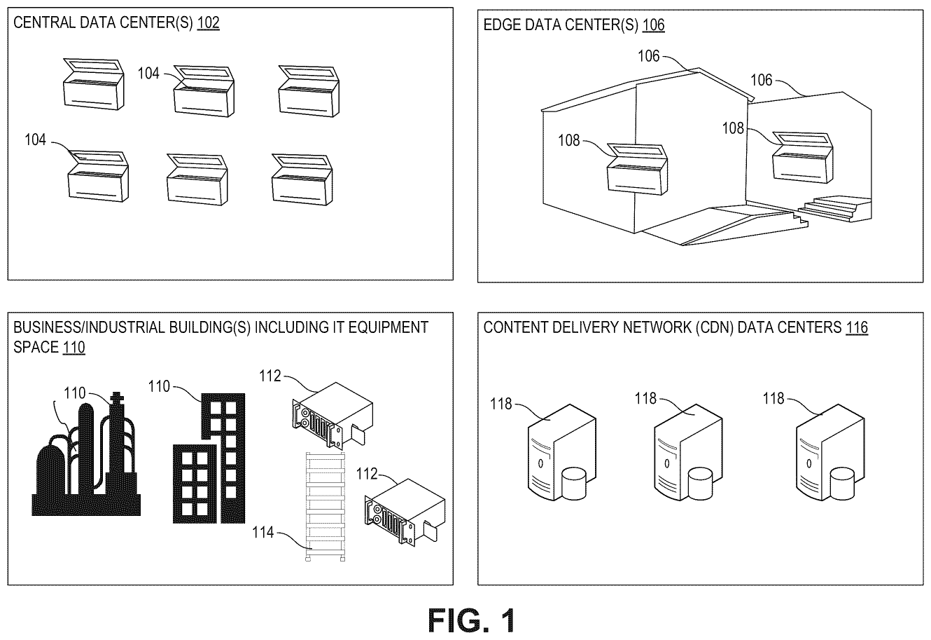

FIG. 1 illustrates one or more example environments in which teachings of this disclosure may be implemented. The example environment(s) of FIG. 1 can include one or more central data centers 102. The central data center(s) 102 can store a large number of servers used by, for instance, one or more organizations for data processing, storage, etc. As illustrated in FIG. 1, the central data center(s) 102 include a plurality of jet impingement cooling system(s) 104 to facilitate cooling of the servers and/or other electronic components stored at the central data center(s) 102.

The example environments of FIG. 1 can be part of an edge computing system. For instance, the example environments of FIG. 1 can include edge data centers or micro-data centers 106. The edge data center(s) 106 can include, for example, data centers located at a base of a cell tower. In some examples, the edge data center(s) 106 are located at or near a top of a cell tower and/or other utility pole. The edge data center(s) 106 include respective housings that store server(s), where the server(s) can be in communication with, for instance, the server(s) stored at the central data center(s) 102, client devices, and/or other computing devices in the edge network. Example housings of the edge data center(s) 106 may include materials that form one or more exterior surfaces that partially or fully protect contents therein, in which protection may include weather protection, hazardous environment protection (e.g., EMI, vibration, extreme temperatures), and/or enable submergibility. Example housings may include power circuitry to provide power for stationary and/or portable implementations, such as AC power inputs, DC power inputs, AC/DC or DC/AC converter(s), power regulators, transformers, charging circuitry, batteries, wired inputs and/or wireless power inputs. As illustrated in FIG. 1, the edge data center(s) 106 can include jet impingement cooling system(s) 108 to cool server(s) and/or other electronic component(s) located at the edge data center(s) 106.

The example environment(s) of FIG. 1 can include buildings 110 for purposes of business and/or industry that store information technology (IT) equipment in, for example, one or more rooms of the building(s) 110. For example, as represented in FIG. 1, server(s) 112 can be stored with server rack(s) 114 that support the server(s) 112 (e.g., in an opening of slot of the rack 114). In some examples, the server(s) 112 located at the buildings 110 include on-premise server(s) of an edge computing network, where the on-premise server(s) are in communication with remote server(s) (e.g., the server(s) at the edge data center(s) 106) and/or other computing device(s) within an edge network. In some examples, the server(s) 112 are cooled during operation with example jet impingement cooling system(s) such as the jet impingement cooling system(s) 104, 108 shown in connection with the data centers 102, 106.

The example environment(s) of FIG. 1 include content delivery network (CDN) data center(s) 116. The CDN data center(s) 116 of this example include server(s) 118 that cache content such as images, webpages, videos, etc. accessed via user devices. The server(s) 118 of the CDN data centers 116 can be disposed in jet impingement cooling system(s) such as the jet impingement cooling system(s) 104, 108 shown in connection with the data centers 102, 106.

In some instances, the example data centers 102, 106, 116 and/or building(s) 110 of FIG. 1 include servers and/or other electronic components that are cooled independent of jet impingement cooling systems (e.g., the jet impingement cooling systems 104, 108). That is, in some examples, some or all of the servers and/or other electronic components in the data centers 102, 106, 116 and/or building(s) 110 can be cooled by air and/or liquid coolants without direct jet impingement on the servers and/or other electronic components therein. Thus, in some examples, the jet impingement cooling systems 104, 108 of FIG. 1 may be omitted.

Although a certain number of jet impingement cooling system(s) and other component(s) are shown in the figures, any number of such components may be present. Also, the example cooling data centers and/or other structures or environments disclosed herein are not limited to arrangements of the size that are depicted in FIG. 1. For instance, the structures containing example cooling systems and/or components thereof disclosed herein can be of a size that includes an opening to accommodate service personnel, such as the example data center(s) 106 of FIG. 1, but can also be smaller (e.g., a “doghouse” enclosure). For instance, the structures containing example cooling systems and/or components thereof disclosed herein can be sized such that access (e.g., the only access) to an interior of the structure is a port for service personnel to reach into the structure. In some examples, the structures containing example cooling systems and/or components thereof disclosed herein can be sized such that only a tool can reach into the enclosure because the structure may be supported by, for a utility pole or radio tower, or a larger structure.

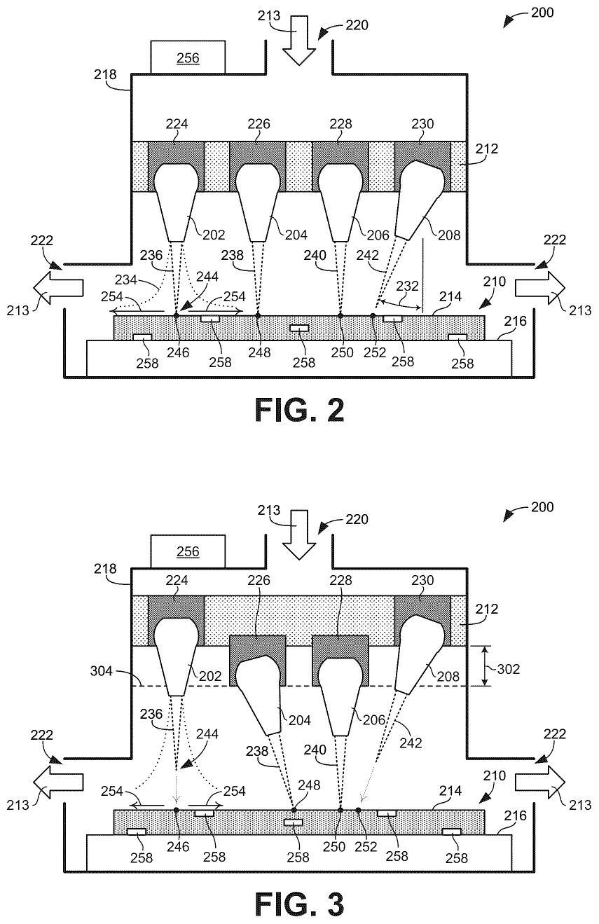

FIG. 2 illustrates an example jet impingement cooling system 200 constructed in accordance with teachings disclosed herein with an array of nozzles 202, 204, 206, 208 that can be independently moved relative to one another and relative to an IC package 210. The IC package 210 can be any suitable type of semiconductor device (e.g., a central processing unit (CPU), a graphics processing unit (GPU) (including general purpose graphics processing units (GPGPUs), a neural processing unit (NPU), an XPU, an accelerator, etc.). In some examples, the jet impingement cooling system 200 corresponds to any one of the jet impingement cooling systems 104, 108 of FIG. 1. While four nozzles 202, 204, 206, 208 are shown in the illustrated example, any suitable number of nozzles may be included. Furthermore, in some examples, the nozzles are arranged in a two-dimensional array overtop of the area or footprint of the IC package 210. In some examples, the IC package is a multi-chip package.

As shown in the illustrated example, the nozzles 202, 204, 206, 208 are supported or carried by a nozzle plate 212 (e.g., an orifice plate) and arranged to impinge cooling fluid 213 on a surface of the IC package 210. The fluid 213 can be any suitable coolant. In some examples, the nozzles 202, 204, 206, 208 include and/or are otherwise associated with individually controlled valves to selectively open and close different ones of the nozzles 202, 204, 206, 208 independent of the others. In some examples, such valves are on/off valves. In other examples, the valves can be adjusted to vary the flow rate through a given nozzle between a fully closed valve position and a fully open valve position. In some examples, valves are omitted and the flow rate is controlled by a single (or more than one) inlet that is directly fluidly coupled to more than one (e.g., all) of the nozzles 202, 204, 206, 208.

In some examples, the nozzles 202, 204, 206, 208 are micronozzles with a height or length (between the inlet and outlet of the nozzles) of approximately 1 millimeter. In other examples, the height or length of the nozzles 202, 204, 206, 208 can be greater than or less than 1 mm (e.g., 0.5 mm, 0.7 mm, 0.9 mm, 1.1 mm, 1.2 mm, 1.5 mm, 2 mm, etc.). In some examples, the upper (e.g., larger) diameter of the nozzles 202, 204, 206, 208 (e.g., the nozzle inlet) is approximately 0.5 mm, but greater or smaller diameters are also possible (e.g., 0.2 mm, 0.3 mm, 0.4 mm, 0.6 mm, 0.7 mm, 1 mm, etc.). Further, in some examples, the lower (e.g., smaller) diameter of the nozzles 202, 204, 206, 208 (e.g., the nozzle outlet) is less than approximately 0.5 mm (e.g., less than or equal to 0.4 mm, less than or equal to 0.3 mm, less than or equal to 0.25 mm, less than or equal to 0.2 mm, less than or equal to 0.125 mm, less than or equal to 0.1 mm, etc.). In some examples, the lower (smaller) diameter is selected in combination with the height or length of the nozzles 202, 204, 206, 208 to produce an aspect ratio (length/diameter) of approximately 8 as this has been experimentally shown to improve (e.g., maximize) efficiency in developing the jet provide upon exit while also improving (e.g., maximizing) the axial velocity profiles of the jet. However, in other examples, nozzles with aspects ratios less than or greater than 8 (e.g., 2, 3, 4, 5, 6, 7, 9, 10, etc.) may also be used.

In this example, the IC package 210 includes a semiconductor die 214 mounted onto a package substrate 216. In some examples, the semiconductor die 214 includes a non-uniform power dissipation architecture that can give rise to hotspots where the temperature of the die 214 is higher at some locations than at other locations. In other examples, the IC package 210 includes multiples dies with different power dissipations resulting in a non-uniform temperature profile for the package 210 when in operation that can give rise to hotspots. In this example, the fluid 213 from the nozzles 202, 204, 206, 208 directly impinges on the surface of the semiconductor die 214. In other examples, the fluid 213 directly impinges on a lid or integrated heat spreader (IHS) included on the package 210 to cover the semiconductor die 214.

In the illustrated example of FIG. 2, the jet impingement cooling system 200 includes a housing 218 to contain the IC package 210 as well as the nozzle plate 212 supporting the nozzles 202, 204, 206, 208. In the illustrated example, the IC package 210 is shown to be entirely enclosed by the housing 218. However, in other examples, the IC package 210 is mounted to a printed circuit board and enclosed between the circuit board and the housing 218. Further, although the nozzle plate 212 is shown as being contained within the housing 218 in the illustrated example, in other examples, the nozzle plate 212 is an integral part of the housing 218. In this example, the housing 218 includes one or more fluid inlets 220 and one or more fluid outlets 222. As shown in the illustrated example, the fluid 213 enters the housing 218 through the inlet(s) 220, passes through the nozzles 202, 204, 206, 208 to directly impinge on the IC package 210, and then leaves the housing 218 through the outlet(s) 222. In some examples, as the fluid 213 impinges on the IC package 210, the fluid draws heat away from the IC package 210 and out the outlet(s) 222. Thus, in this example, the temperature of the fluid 213 at the outlet(s) 222 is higher than the temperature of the fluid 213 at the inlet(s) 220.

In some examples, the nozzle plate 212 includes a plurality of orifices to permit the fluid 213 to pass through the nozzle plate 212 to the nozzles 202, 204, 206, 208 disposed in and/or adjacent to the orifices. In some examples, the nozzles 202, 204, 206, 208 are supported by and/or contained within nozzle seat assemblies 224, 226, 228, 230 that are coupled to corresponding ones of the orifices in the nozzle plate 212. In some examples, the nozzle seat assemblies 224, 226, 228, 230 facilitate the ability of the nozzles 202, 204, 206, 208 to move relative to one another and relative to the nozzle plate 212. Further detail regarding the implementation of the nozzle seat assemblies 224, 226, 228, 230 and how the nozzles 202, 204, 206, 208 are able to move is provided below. In brief, in some examples, the nozzles 202, 204, 206, 208 are coupled to respective ones of the nozzle seat assemblies 224, 226, 228, 230 with a gimballed connection to enable the nozzles 202, 204, 206, 208 to rotate relative to the nozzle seat assemblies 224, 226, 228, 230 about one or more of an X axis, a Y axis, and a Z axis. For purposes of explanation, the X and Y axes are defined in the plane of the IC package 210 and the Z axis is perpendicular to the IC package 210. As shown in the illustrated example of FIG. 2, while each of the first three nozzles 202, 204, 206 are oriented orthogonally to the IC package 210 (e.g., pointed directly downward along the Z axis), the fourth nozzle 208 is oriented at an angle 232 relative to the orthogonal (Z axis direction). In some examples, the angle 232 can be as great as 25 degrees or more (e.g., up to 30 degrees, up to 35 degrees, up to 40 degrees, up to 45 degrees, up to 50 degrees, up to 55 degrees, up to 60 degrees, etc.).

In some examples, nozzles in an orthogonal position relative to the IC package 210 (e.g., the first, second, and third nozzles 202, 204, 206 in FIG. 2) are in a default or baseline position. For purposes of explanation and clarity, the impingement of a jet stream produced by a nozzle in the baseline position (e.g., the orthogonal position) is referred to herein as “jet impingement” or “orthogonal impingement”. By contrast, when a nozzle is angled relative to the orthogonal or baseline position (e.g., the fourth nozzle 208 in FIG. 2), the impingement of the resulting jet stream is also angled and referred to herein as “jet vectored impingement” or “targeted impingement” to indicate the angle, direction, or vector of the nozzle is intentionally and/or dynamically controlled to target a particular location (e.g., a particular hotspot) on the IC package 210. Further, as used herein, “jet vectoring” refers to the process or action of moving a nozzle to a particular (angled) position to produce corresponding jet vector impingement of cooling fluid on the IC package 210. That is, as disclosed herein, any given nozzle can be dynamically adjusted, gimballed, or “jet vectored” to a given position to target a particular location (e.g., hotspot) on the IC package 210.

In the illustrated example of FIG. 2, an outer boundary 234 of a jet stream from the first nozzle 202 is shown. Additionally, the potential core 236 of the jet stream from the first nozzle 202 is also shown. Potential cores 238, 240, 242 are also shown for jet streams from the second, third, and fourth nozzles 204, 206, 208. For purposes of clarity and simplicity, the outer boundaries of the jet streams for the second, third, and fourth nozzles 204, 206, 208 are omitted. The potential core of a jet stream is a central region of the jet stream that has a nearly uniform mean velocity with a maximum velocity at the distal end 244 of the potential core 236. The velocity of the fluid 213 begins to decrease at distances beyond the distal end 244 of the potential core 236. The length of the potential core from the nozzle outlet to the distal end 244 of the potential core has been experimentally shown to be about 6 to 8 times the diameter of the nozzle outlet. Heat transfer from a surface due to jet impingement cooling increases as the velocity of the fluid impinging on the surface increases. Accordingly, as shown in the illustrated example, the IC package 210 is positioned at or near the distal end 244 of the potential cores 236, 238, 240, 242 to increase (e.g., maximize) heat transfer. In some examples, the IC package 210 is positioned closer to the nozzles 202, 204, 206, 208 (e.g., inside the extent of the potential cores 236, 238, 240, 242). In other examples, the IC package 210 is positioned farther away from the nozzles 202, 204, 206, 208 (e.g., beyond the distal end 244 of the potential cores 236, 238, 240, 242, in the fully developed region of the jet streams). In some examples, the distance of the nozzles 202, 204, 206, 208 from the IC package 210 (also known as the standoff distance or z-height) can be any suitable distance (e.g., 0.5 mm, 0.75 mm, 1 mm, 1.5 mm, 2 mm, 3 mm, etc.).

For purposes of illustration, FIG. 2 includes first, second, third, and fourth target points 246, 248, 250, 252 along the upper surface of the IC package 210 corresponding to target locations for the jet streams from the respective first, second, third, and fourth nozzles, 202, 204, 206, 208. As shown in the illustrated example, the first, second, and third target points 246, 248, 250 are directly below the first, second, and third nozzles, 202, 204, 206 because the nozzles are in a baseline orthogonal position relative to the IC package 210. This is the typical arrangement of nozzles in known jet impingement cooling systems. However, unlike the other target points 246, 248, 250, the fourth target point 252 is offset relative to the fourth nozzle 208. More particularly, in this example, the fourth target point 252 is offset in a direction towards the third target point 250. In other examples, the fourth target point 252 can be offset in any other direction in the XY plane corresponding to the upper surface of the IC package 210. The amount of the offset is determined by the size of the angle 232. Adjusting, tilting, or rotating nozzles to move the target location towards which an associated jet stream is directed can enable the targeting of higher temperature areas (e.g., current hotspots) and/or potential areas where the temperature is expected to rise (e.g., future hotspots) to help cool those hotspots and mitigate against Tⱼ-rises at those locations. This is particularly useful when the areas directly below a particular nozzle are not associated with a hotspot. That is, in the illustrated example of FIG. 2, the angled orientation of the fourth nozzle 208 may be suitable when the area near the third target point 250 (e.g., underneath the third nozzle 206) is associated with a hotspot (current or future) while the area on the IC package 210 directly underneath the fourth nozzle 208 exhibits less concern for rising temperatures.

In some examples, the maximum amount of offset between the target of a nozzle (e.g., the target point 252 associated with the fourth nozzle 208) and the orthogonal position of the nozzle is defined by the maximum angle 232 by which the nozzle can be tilted. In some cases, it may be beneficial to direct a nozzle to a target point beyond the extent that the nozzle can be tilted. Accordingly, in some examples, the nozzle plate 212 is constructed to selectively move away from the IC package 210 while lifting one or more of the nozzles at the same time, thereby increasing the distance between such nozzles and the IC package 210, as shown in the illustrated example of FIG. 3. More particularly, as shown in FIG. 3, the first and fourth nozzles 202, 208 are lifted with the nozzle plate 212 by a distance 302 from a baseline position 304. As a result of the fourth nozzle 208 being raised, the fourth target point 252 is able to move closer to the third target point 252, even though the angle 232 of the fourth nozzle 252 has not changed relative to the arrangement shown in FIG. 2. In some examples, the nozzle plate 212 includes a main portion and a secondary portion that moves relative to the main portion. In some such examples, the secondary portion (also referred to herein as an actuator plate) is moveable relative to the main portion and/or relative to the housing 218 to lift selective ones of the nozzles (e.g., the first and fourth nozzles 202, 208), while the main portion of the nozzle plate 212 remains fixed relative to the housing (and the IC package 210) to hold the nozzles that are not being raised (e.g., the second and third nozzles 204, 206).

Reaching target locations farther away from the orthogonal position of a nozzle is not the only reason to lift a nozzle away from an IC package 210. Rather, another significant reason to raise a nozzle is to reduce the effects of cross flow as explained by reference to the raising of the first nozzle 202 in FIG. 3 relative to the position shown in FIG. 2. As mentioned above, the velocity of a jet stream is at a maximum at the end (e.g., the distal end 244) of the potential core of the jet stream (e.g., the potential core 236 associated with the first nozzle 202). Once the fluid in the jet stream hits or impinges on the surface of the IC package 210, the fluid has nowhere else to go but radially outward from the initial flow direction of the jet stream. This outward flow of fluid after impingement is referred to as cross flow and is represented in FIGS. 2 and 3 by the arrows identified by reference number 254. A jet stream that impinges on a surface at higher velocity will result in greater cross flow.

Cross flow can have a negative impact on the heat transfer

efficiency of adjacent jet streams because the cross flow, as its name suggests, crosses the path or flow of an adjacent jet stream, thereby disrupting the impingement of the adjacent jet stream on the surface to be cooled. That is, as shown in FIG. 2, the cross flow 254 from the jet stream associated with the first nozzle 202 travels across the surface of the IC package 210 until it crosses the second target point 248 towards which the jet stream of the second nozzle 204 is directed. In this example, the jet stream of the second nozzle 204 will produce a similar cross flow that extends radially outward from the second target point 248 that is not shown for purposes of clarity and simplicity. Such cross flow can have a deleterious effect on heat transfer efficiency of both jet streams. Accordingly, in examples, where heat transfer associated with one of the jet streams is more important than the other (e.g., is cooling an area at a higher temperature (e.g., a hotspot)), the nozzle associated with the other jet stream can be raised up, as illustrated in FIG. 3. Specifically, as shown in FIG. 3, the first nozzle 202 is raised with the nozzle plate 212 such that the first target point 246 is now well beyond the distal end 244 of the potential core 236 of the first jet stream. As a result, the fluid 213 in the jet stream impinges on the surface of the IC package 210 at a much slower velocity, thereby resulting in a decrease in the cross flow 254 relative to the arrangement shown in FIG. 2. The smaller cross flow will have less of an impact on the jet stream associated with the second nozzle 204, thereby increasing the heat transfer at the second target point 248 associated with the second nozzle 204. The lower velocity of the jet stream impinging on the IC package 210 form the first nozzle 202 in FIG. 3 will result in a reduction of heat transfer relative to the higher impingement velocity in the arrangement shown in FIG. 2. However, this arrangement is suitable when the first target point 246 is not at a raised temperature (e.g., is not an actual hotspot) that needs cooling and does not pose any significant risk of significantly increasing in temperature (e.g., is not a future hotspot).

In some examples, as shown in FIG. 3, not all of the nozzles 202, 204, 206, 208 are raised when the nozzle plate 212 (or an associated actuator plate) is raised. Rather, in some examples, each of the nozzles 202, 204, 206, 208 can be selectively coupled or decoupled from movement with (e.g., placed in fixed spatial relationship with) the nozzle plate 212. Thus, in this example, the second and third nozzles, 204, 206 remain at the baseline position 304 while the first and fourth nozzles 202, 208 are raised with the nozzle plate (or an associated actuator plate). More generally, in some examples, any one of the nozzles 202, 204, 206, 208 can selectively move relative to the nozzle plate 212 in a direction orthogonal to the IC package 210 or move with the nozzle plate 212 as the nozzle plate 212 (or an associated actuator plate) moves away or towards the IC package 210. Further, the nozzles 202, 204, 206, 208 are able to rotate or tilt relative to the nozzle plate 212 regardless of whether the nozzles 202, 204, 206, 208 are secured to the nozzle plate 212 or an associated actuator plate to move therewith (as in the case of the first and fourth nozzles 202, 208) or are maintained at the baseline position 304 spaced apart from the position of the nozzle plate 212 or an associated actuator plate (as in the case of the second and third nozzles 204, 206). Thus, as shown in FIG. 3, the second nozzle 204 is tilted relative to the previously orthogonal position shown in FIG. 2.

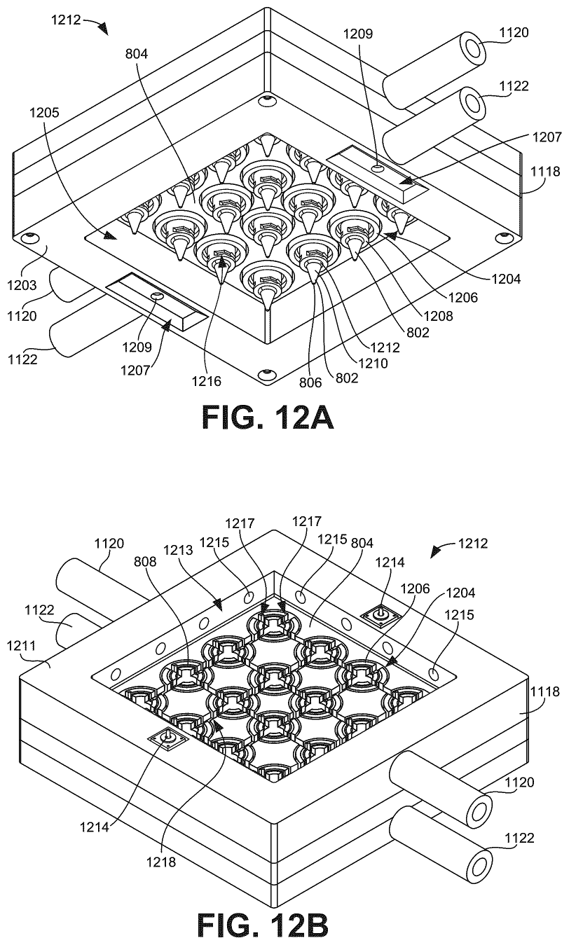

In some examples, any one of the nozzles 202, 204, 206, 208 can switch between the baseline position 304 and a raised position independent of movement of the nozzle plate 212 (or an associated actuator plate). That is, in some examples, it is possible to raise the second nozzle 204, shown in FIG. 3, up to the nozzle plate 212 already in the raised position (e.g., to shift the second target point 248 in FIG. 3 closer to the third target point 250). Likewise, in some examples, it is possible to lower the first nozzle, shown in FIG. 3, down to the baseline position 304 while retaining the nozzle plate 212 in the raised position. In some examples, the relative vertical movement between the nozzles 202, 204, 206, 208 and the nozzle plate 212 is enabled by the coupling between the nozzle seat assemblies 224, 226, 228, 230 and the nozzle plate 212. More particularly, in some examples, each of the nozzle seat assemblies 224, 226, 228, 230 include an armature that is selectively moveable by a magnetic force generated by a corresponding electromagnet in the nozzle plate 212 (or an associated actuator plate). More particular, in some examples, when the electromagnet is activated or energized, the corresponding nozzle seat assembly 224, 226, 228, 230 (and, thus, the corresponding nozzle 202, 204, 206, 208) is secured in fixed relationship with the nozzle plate 212 (or an associated actuator plate) to move therewith. If the nozzle plate 212 (or an associated actuator plate) is already raised relative to the baseline position 304 when the electromagnet is energized, then the corresponding nozzle seat assembly 224, 226, 228, 230 (and, thus, the corresponding nozzle) will be lifted up to the raised position of the nozzle plate 212. In some examples, the nozzle seat assemblies 224, 226, 228, 230 include a spring or other biasing element to urge the assemblies to the baseline position whenever the corresponding electromagnet is deactivated or deenergized. Thus, in some examples, each of the nozzles 202, 204, 206, 208 can be raised or lowered independent of the other nozzles. In some examples, the extent that the nozzle(s) that are raised relative to the baseline position 304 is defined by the distance 302 that the nozzle plate 212 (or an associated actuator plate) is raised relative to the baseline position 304. In some examples, the nozzle plate 212 (or an associated actuator plate) can be raised to any desired distance 302 along a range of the travel path of the nozzle plate 212. In some examples, the full range of the travel path (e.g., the maximum distance 302) is at least 2 millimeters (mm) or more (e.g., at least 3 mm, at least 5 mm, at least 7 mm, at least 10 mm, etc.). Further details regarding the implementation of the nozzle seat assemblies 224, 226, 228, 230 are provided below in connection with FIGS. 12-25.

In some examples, the jet impingement cooling system 200 includes example controller circuitry 256 (e.g., one or more microcontrollers) to control the operations of the cooling system 200. That is, in some examples, the controller circuitry 256 is communicatively coupled to actuators that enable the nozzles 202, 204, 206, 208 to be rotated and/or tilted relative to their respective nozzle seat assemblies 224, 226, 228, 230. Further, in some examples, the controller circuitry is communicatively coupled to actuators that cause the nozzle plate 212 (or an associated actuator plate) to rise and lower relative to the IC package 210. Further still, in some examples, the controller circuitry 256 activates and/or deactivates the electromagnets that cause the nozzle seat assemblies 224, 226, 228, 230 to be selectively secured (or raised and then secured) into fixed relationship the nozzle plate 212 (or an associated actuator plate).

In some examples, the controller circuitry 256 determines the arrangement and/or orientation of the nozzles 202, 204, 206, 208 (e.g., the angle and direction of tilt, whether to be raised or left at the baseline position 304, and the distance 302 by which they are to be raised) based on temperature data obtained from one or more temperature sensor 258 (e.g., a digital temperature sensor (DTS)) monitoring the temperature of the IC package 210 in substantially real time. In some examples, as represented in the illustrated example, the temperature sensors 258 can be on an upper surface of the IC package 210 (e.g., the surface on which jet streams from the nozzles 202, 204, 206, 208 impinge), on a bottom surface of the semiconductor die 214 in the package 210, and/or embedded within the semiconductor die 214 (e.g., between the upper and bottom surfaces of the die). In some examples, there is only one temperature sensor 258. In other examples, any other suitable number of temperature sensors 258 may be included. In some examples, the temperature sensors 258 are located near locations in or on the semiconductor die 214 that are known (or expected) to produce relatively high amounts of heat (e.g., are locations associated with potential hotspots).

In some examples, the controller circuitry 256 obtains and evaluates temperature data associated with the IC package 210 (e.g., from the temperature sensors 258) to determine the current temperature profile of the IC package 210 and/or to identify areas and/or locations associated with current hotspots (e.g., areas where the temperature satisfies (e.g., exceeds) a threshold and/or where the temperature results in a temperature differential relative to other areas (e.g., a temperature gradient) that satisfies (e.g., exceeds) a temperature differential threshold). In some examples, based on the determination or identification of current hotspots, the controller circuitry 256 determines target locations (e.g., the target points 246, 248, 250, 252) towards which each nozzle 202, 204, 206, 208 is to be directed to reduce the temperature of the hotspots.

Additionally or alternatively, in some examples, the controller circuitry 256 determines the arrangement and/or orientation of the nozzles 202, 204, 206, 208 based on predictive data associated with the operation of the IC package 210. As used herein, predictive data is any data that can be used to predict future heat generation of an IC package and/or more particularly predict or determine the location where such heat generation is to originate. That is, predictive data is used to identify the presence and location of future hotspots as defined above. In some examples, the predictive data includes workload data indicative of imminent workloads of the IC package. In some examples, the predictive data includes schedule data from a task scheduler associated with the IC package that indicates tasks scheduled for implementation by the IC package. In some examples, the predictive data may indicate the particular portion or region of an IC package that is to perform a given task or operation. For instance, the predictive data can identify a particular tile (e.g., a particular core) and/or the location of a particular block of circuitry in a monolithic semiconductor die associated with a future task or operation to be performed to identify the area where heat is to be produced once the task or operation is initiated. In some examples, the predictive data includes machine learning output data generated by a machine learning model that has been trained on historical data including job placement of workloads and associated hotspots and/or temperature profiles resulting from such job placements.

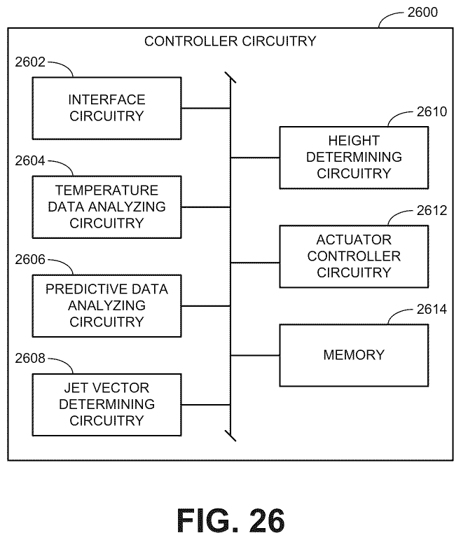

In the illustrated example of FIGS. 2 and 3, the controller circuitry 256 is coupled to an exterior of the housing 218 of the jet impingement cooling system 200. In other examples, the controller circuitry 256 can be at any other suitable location (e.g., inside the housing, spaced apart from the housing, etc.). Further, in some examples, the function of the controller circuitry 256 may be distributed across different blocks of circuitry at different locations. Further details regarding the implementation of the example controller circuitry 256 are provided below in connection with FIGS. 26-28.

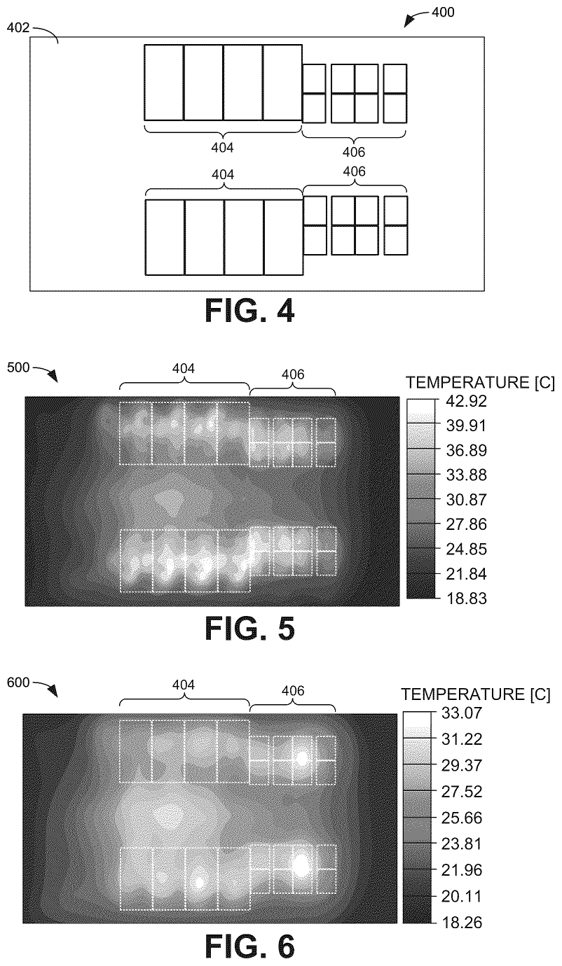

FIG. 4 illustrates an example layout of an example IC package 400 based on a single monolithic semiconductor die 402 on which Reynolds-averaged Navier-Stokes (RANS) CFD simulations have been performed to show the improvement in temperature control achieved through the implementation of teachings disclosed herein. In the illustrated example, the IC package 400 is a processor with a multi-core architecture. Specifically, the example IC package 400 includes two types of processor cores including performance cores 404 and efficiency cores 406. In this example, the IC package 400 includes eight performance cores 404 arranged in two rows of four, and sixteen efficiency cores 406 in two groupings of eight cores arranged in two rows of four. As their name implies, the performance cores 404 are designed to enhance (e.g., maximize) performance, whereas the efficiency cores 406 are designed to enhance (e.g., maximize) power efficiency. There is a tradeoff between enhancing performance and enhancing efficiency. Thus, while the performance cores 404 provide better performance than the efficiency cores 406, the performance cores 404 use more power than the efficiency cores 406. As a result, the performance cores 404 are expected to generate more heat with the highest temperatures (e.g., hotspots) on the semiconductor die 402 at the locations associated with performance cores 404.

For purposes of the CFD simulations, a total of sixteen jet impinging nozzles are modelled as impinging on the semiconductor die 402. In the CFD model, each performance core 404 has a dedicated nozzle directly impinging thereon when in a baseline orthogonal position that accounts for eight of the sixteen nozzles. The eight remaining nozzles are orthogonally directed to different pairs of the efficiency cores 406. FIG. 5 illustrates an example temperature profile 500 resulting from a CFD simulation of the IC package 400 of FIG. 4 with all sixteen nozzles maintained in the baseline position to orthogonally impinge fluid on to the different cores 404, 406. That is, FIG. 5 represents the resulting temperature profile for the IC package 400 without the benefits of the dynamic adjustment of the angle or tilt of the nozzles for jet vector impingement of cooling fluid on target locations associated with hotspots (e.g., actual hotspots and/or future hotspots). As represented in FIG. 5, the highest temperatures are at locations associated with the performance cores 404, with the highest temperature being above 42.9 degrees Celsius. This results in a relatively large temperature gradient across the IC package 400 with the lowest temperature being less than 18.9 degrees Celsius (e.g., a temperature differential of approximately 24 degrees Celsius).

FIG. 6 illustrates an example temperature profile 600 resulting from a CFD simulation of the IC package 400 of FIG. 4 with the sixteen nozzles discussed above being dynamically adjusted for jet vector impingement to respond to and mitigate hotspots (e.g., actual hotspots and/or future hotspots). More particularly, in the illustrated example of FIG. 6, two of the eight nozzles positioned orthogonally above the efficiency cores 406 are modelled as providing a jet vectored impingement of cooling fluid on the performance cores 404. That is, whereas FIG. 5 represents eight nozzles impinging on the performance cores 404 and eight nozzles impinging on the efficiency cores 406, in the example of FIG. 6, ten nozzles are impinging on the performance cores 404 and only six nozzles are impinging on the efficiency cores 406. Further, in the illustrated example of FIG. 6, the jet vectored nozzles are assumed to be adjusted into position prior to a change in workload of the performance cores 404. That is, the simulation is based on the dynamic adjustment of the nozzles based on preemptive cooling of future hotspots.

As shown in FIG. 6, the additional cooling fluid from the jet vectored nozzles on the performance cores 404 reduces the temperature at locations associated with the performance cores 404 such that they are no longer associated with the highest temperature on the surface of the IC package 400. Rather, the highest temperature is located at regions associated with the efficiency cores 406. However, as demonstrated by the temperature scale in FIG. 6, the highest temperature is less than 33.1 degrees Celsius, which is a drop of nearly 10 degrees relative to the highest temperature (e.g., 42.9 degrees) in the example of FIG. 5. Thus, not only does the jet vectoring of the nozzles to impinge additional cooling fluid onto the performance cores 404 eliminate the hotspots associated with the performance cores 404, the jet vectored nozzles also reduce the overall temperature gradient across the IC package 400 (e.g., to a temperature differential of less than 15 degrees in the illustrated example). In other words, a comparison of the temperature profile 500 of FIG. 5 with the temperature profile 600 of FIG. 6 demonstrates that the existing technique of using nozzles in a fixed orthogonal position may be insufficient to adequately decrease or arrest a Tⱼ-rise. However, with the additional nozzles (e.g., jet vectored nozzles) directed towards the performance cores 404, the Tⱼ can be significantly reduced.

The temperature profiles 500, 600 shown in FIGS. 5 and 6 are based on simulations using nozzles modelled with an outlet diameter of 0.125 mm and a length or height of 1 mm (for an aspect ratio of 8). Further, in the illustrated examples, the modelled nozzles were positioned at a standoff distance (z height) from the IC package 400 of 1 mm, and the Reynolds number as assumed to be 8000. Similar simulations were performed with changes to the Reynolds number (e.g., Reynolds numbers of 12000, 16000, 20000, 240000) and to the standoff distance (e.g., z heights of 2 mm and 3 mm). In each simulation, similar results were found with a reduction of Tⱼ of approximately 10 degrees Celsius.

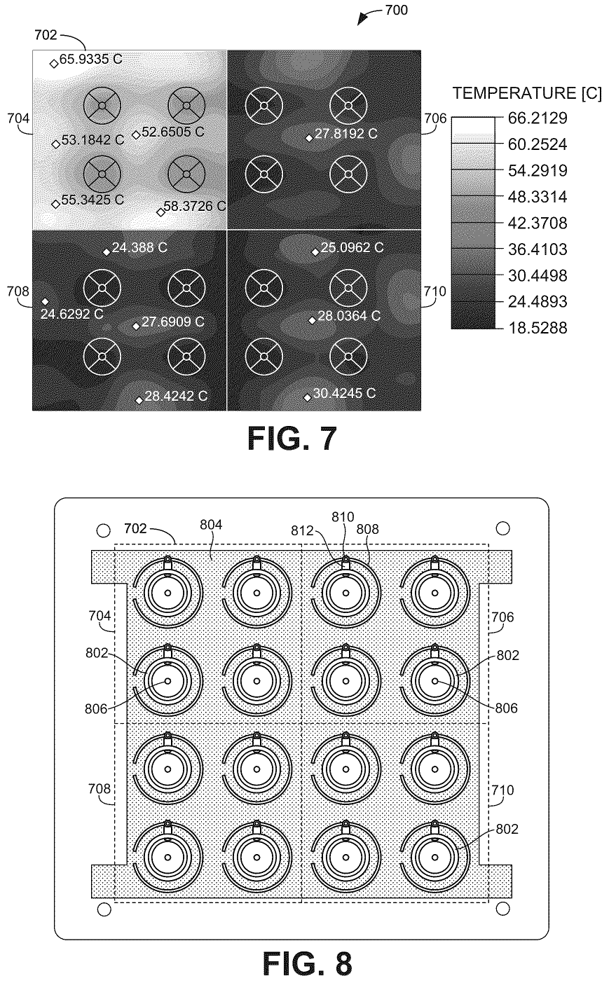

Teachings disclosed herein are not limited to the example arrangement of cores 404, 406 shown in the example IC package of FIG. 4 with the corresponding arrangement of sixteen nozzles as described above. Rather, any suitable arrangement of any number of nozzles can be implemented to dynamically cool any type of IC package. For instance, in some examples, the jet vectoring of nozzles to dynamically adjust locations of jet streams to cool locations of hotspots (including preemptively cooling future hotpots) can be applied to multi-chip packages as represented in FIG. 7. More particularly, FIG. 7 is an example temperature profile 700 for an example IC package 702 (e.g., a multi-chip module (MCM)) that includes four individual chiplets or tiles 704, 706, 708, 710 (e.g., a quad-tile bare die package). The example temperature profile 700 of FIG. 7 is based on a CFD simulation in which each die is being cooled by four nozzles (for a total of sixteen) at locations represented by the crosshairs in FIG. 7. FIG. 8 illustrates a top view of an example physical arrangement of nozzles 802 supported by a nozzle plate 804 over top of the IC package 702 of FIG. 7 (represented in dashed lines in FIG. 8). FIG. 8 represents an example implementation of the jet impingement cooling system 200 of FIG. 2. Thus, in some examples, the nozzles 802 of FIG. 8 may correspond to the nozzles 202, 204, 206, 208 of FIG. 2 and the corresponding description of the nozzles 202, 204, 206, 208 provided in connection with FIG. 2 applies equally to the nozzles 802 in FIG. 8. Likewise, in some examples, the nozzle plate 804 of FIG. 8 may correspond to the nozzle plate 212 of FIG. 2 and the corresponding description provided in connection with FIG. 2 applies equally to the nozzle plate 804 in FIG. 8.

The perspective shown in FIG. 8 is looking down the inside of the cone of the nozzles 802 with the small circle 806 at the center of each nozzle 802 representing the nozzle outlet at the tip of each nozzle 802. As shown in the illustrated example, the nozzle outlet 806 of each nozzle 802 is centered on the nozzle to indicate that the nozzles 802 of the illustrated example are all maintained in the baseline position to orthogonally impinge fluid onto the different tiles 704, 706, 708, 710.

In the illustrated example of FIG. 8, C-shaped slots 808 in the nozzle plate 804 extend around the location of corresponding ones of the nozzles 802 to facilitate the dynamic adjustment (e.g., jet vectoring) of the nozzles 802. More particularly, in some examples, a nozzle 802 (located on one side of the nozzle plate 804) is operatively coupled to a motor (located on the other side of the nozzle plate 804) by way of connecting rod 810 that extends through the corresponding C-shaped slot 808. More particularly, in some examples, the nozzles 802 are on the side of the nozzle plate 804 facing towards the IC package 702. That is, the nozzles 802 are behind the nozzle plate 804 from the perspective shown in FIG. 8. However, for purposes of explanation and clarity, the nozzles are shown in solid lines without the shading of the nozzle plate 804 extending across the nozzles 802. In some examples, as the motor coupled to a nozzle 802 rotates, the connecting rod 810 will move along the C-shaped slot 808. In such examples, as the rod 810 moves about the slot 808, the nozzle 802 will rotate about a central axis because the connecting rod 810 is coupled to the nozzle 802 (by an anchor 812). This rotation of the nozzle 802 based on movement of the connecting rod 810 also results in changes to the angle the nozzle 802 is tilted relative to the baseline orthogonal position as detailed further below.

In the 4-tile die configuration of the example IC package 702, the power in the four tiles 704, 706, 708, 710 dynamically changes dependent on the power-differing schemes such as artificial intelligence, high-performance computing, and cloud services workloads being implemented by each of the tiles 704, 706, 708, 710. In the example simulation represented in FIG. 7, the first tile 704 (upper left corner) is dissipating more power than the other three tiles 706, 708, 710 and, thus, is hotter than the other three tiles 706, 708, 710. More particularly, in this example, the highest temperature on the first tile 704 is around 66 degrees Celsius. By contrast, the highest temperature on each of the other tiles 706, 704, 708 is around 30 degrees Celsius.

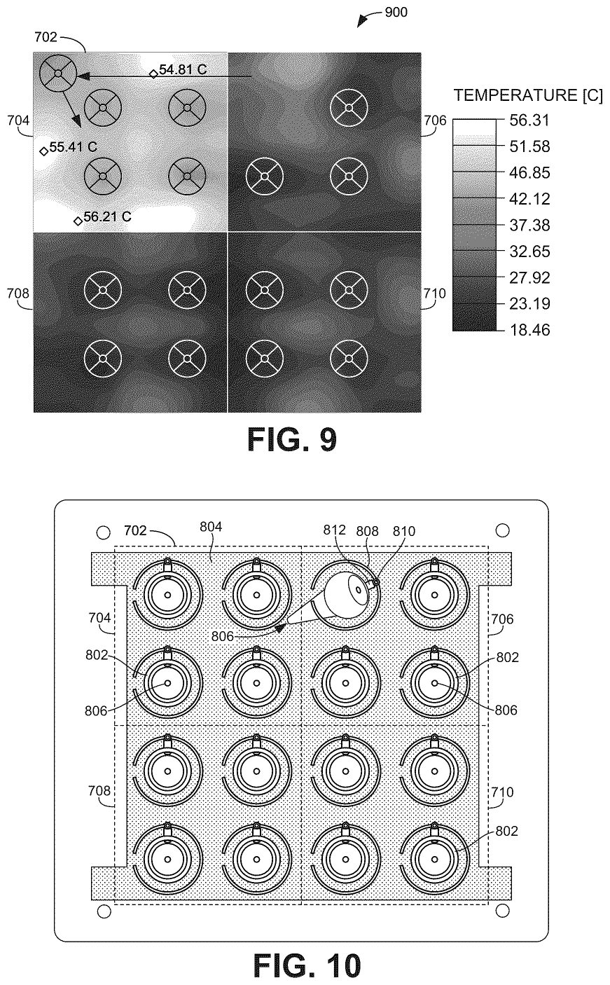

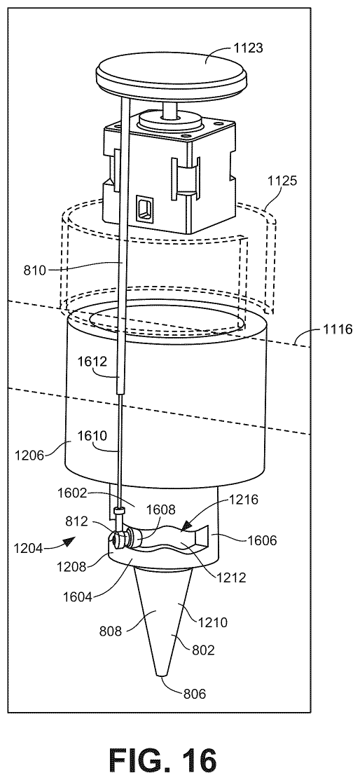

FIG. 9 illustrates an example temperature profile 900 resulting from a CFD simulation of the IC package 702 of FIG. 7 with the same nozzles 802 discussed above in connection with FIG. 8 except that one of the nozzles 802 is modelled as being jet vectored to provide jet vector impingement of additional cooling fluid on the first tile 704. More particularly, this scenario is modelled in the simulation by moving the location of one of the nozzles previously providing jet impingement on the second tile 706 (when in the orthogonal position) to impinge on the first tile 704. In actual implementation, the nozzle 802 does not change locations and, instead, is merely angled or tilted to be directed towards the first tile 704. This is represented in the illustrated example of FIG. 10. As shown, one of the nozzles has been tilted so that the outlet 806 of the nozzle 802 is pointed towards the first tile 706. As shown in the illustrated example, this tilting or jet vectoring of the nozzle 802 is achieved by moving the connection rod 810 about the C-shaped slot 808 in the nozzle plate 804. Further details regarding the adjustment of the nozzle 802 are provided below in connection with FIGS. 16-25.

The effect of the adjustment of the nozzle 802 on the temperature of the IC package 702 is represented by the simulated data in the temperature profile 900 of FIG. 9. Specifically, as shown, the highest temperature on the first tile 704 is maintained around 56 degrees Celsius, which is a drop of about 10 degrees relative to the highest temperature on the first tile 704 in the temperature profile 700 of FIG. 7. While this adjustment results in a slight rise in the temperature of the second tile 706, this is not of great concern because the second tile 706 is not dissipating significant amounts of power and, therefore, not producing a significant amount of heat. Further simulations have been shown that an additional drop of about 10 degrees Celsius on the first tile 704 (e.g., to a highest temperature of approximately 46 degrees Celsius) can be achieved by jet vectoring another nozzle onto the first tile 704 that has a baseline orthogonal position directed towards the third tile 708. As such, examples based on jet vectoring of nozzles to cool hotspots (including preemptive cooling of future hotspots) as disclosed herein can significantly reduce or arrest increases in temperatures relative to known jet impingement systems that are limited to orthogonal impingement. Further, the reduced temperature of localized hotspots (e.g., reduction in Tⱼ rise) also enables a reduction in the overall temperature gradient of the IC package 702.

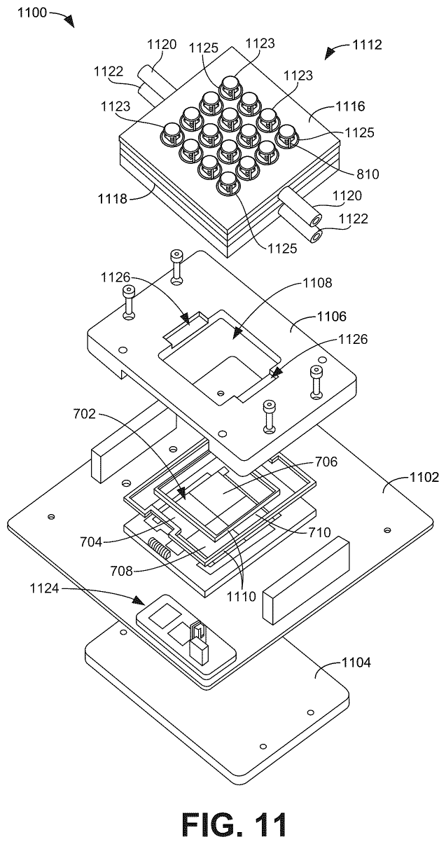

FIG. 11 is an exploded view of an example jet impingement cooling system 1100 constructed in accordance with teachings disclosed herein. The jet impingement cooling system 1100 of FIG. 11 is a more detailed example implementation of the jet impingement cooling system of 200 of FIG. 2 based on the arrangement of nozzles as shown in FIGS. 7-10. Accordingly, the same reference numbers used in FIGS. 7-10 will be used for the same or similar features shown in FIG. 11 and the description of such features above applies equally to the corresponding features of FIG. 11. For purposes of explanation, the example jet impingement cooling system 1100 is arranged to cool the example IC package 702 of FIGS. 7-10 that includes the four separate semiconductor tiles 706. However, the example jet impingement cooling system 1100 can be modified and/or adapted to cool any other IC package (e.g., the IC package 210 of FIG. 2, the IC package 400 of FIG. 4, etc.).

As shown in the illustrated example of FIG. 11, the IC package 702 is mounted to a printed circuit board (PCB) 1102 that is sandwiched between a backplate 1104 (on an opposite side of the PCB 1102 to the IC package 702) and a bolster retention plate 1106. In some examples, the bolster retention plate 1106 extends over the IC package 702 but includes an opening 1108 to expose the IC package 702 therethrough. In some examples, one or more gaskets 1110 are positioned adjacent to and around the IC package 702 to provide a seal between components once the bolster retention plate 1106 is attached to the backplate 1104 through the PCB 1102.

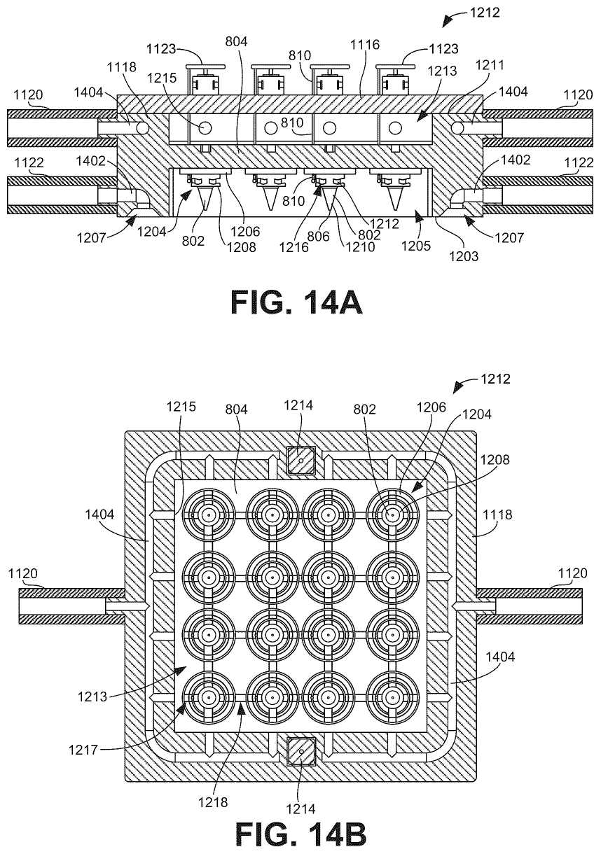

In this example, the jet impingement cooling system 1100 includes a nozzle plate assembly 1112 that functions as the housing (e.g., the housing 218 of FIG. 2) that contains the array of nozzles 802 over the IC package 702 and also contains and/or supports the actuators that enable the nozzles 802 to be adjusted (e.g., rotated, tilted, raised, lowered, etc.). The arrangement of the nozzles 802 and the associated mechanisms to control their movement is detailed further below in connection with FIGS. 12-25. In the illustrated example, the nozzle plate assembly 1112 includes an actuator plate 1116 and a nozzle enclosure 1118. In some examples, the nozzle enclosure 1118 is integrally formed with (e.g., includes, defines) the nozzle plate 804 as shown in greater detail in FIGS. 12A and 12B (collectively referred to herein as FIG. 12) and FIG. 14A and 14B (collectively referred to herein as FIG. 14). As shown in FIG. 11, the nozzle enclosure 1118 includes and/or defines one or more cooling fluid inlets 1120 to introduce the cooling fluid (e.g., the fluid 213 of FIG. 2) into the nozzle plate assembly 1112. Further, in this example, the nozzle enclosure 1118 includes and/or defines one or more cooling fluid outlets 1122 out of which the cooling fluid exits the nozzle plate assembly 1112 after drawing heat away from the IC package 702. In this example, there are two fluid inlets 1120 and two fluid outlets 1122 with one of each of the inlets 1120 and outlets 1122 on opposite sidewalls of the nozzle enclosure 1118. In other examples, there may be only one fluid inlet 1120 and/or only one fluid outlet 1122. In other examples, there may be more than two fluid inlets 1120 and/or more than two fluid outlets 1122. Further, in some examples, the fluid inlets 1120 and the fluid outlets 1122 can be at any other suitable location (e.g., on the same side of the nozzle enclosure 1118, on the actuator plate 1116, etc.).

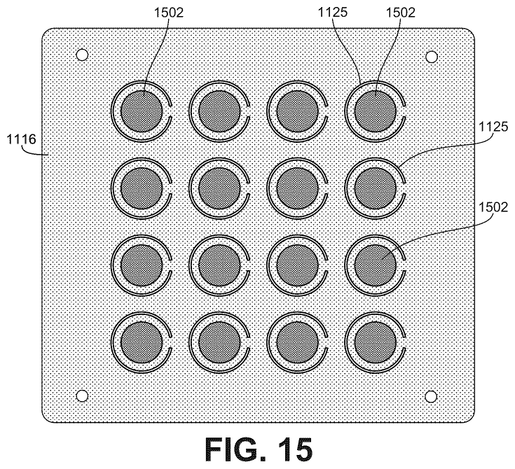

In some examples, the actuator plate 1116 includes, carries, and/or supports various actuators and/or other mechanisms to control movement of the nozzles 802 within the nozzle plate assembly 1112. More particularly, as shown in the illustrated example of FIG. 11, the actuator plate 1116 includes an array of rotary motors 1123 aligned with corresponding ones of the nozzles 802 inside the nozzle plate assembly 1112. In some examples, the rotary motors 1123 are positioned inside a C-shaped slots 1125 that extends through the actuator plate 1116. In this example, the C-shaped slots 1125 in the actuator plate 1116 are aligned with corresponding ones of the C-shaped slots 808 in the nozzle plate 804 discussed above in connection with FIGS. 8 and 10. As with the slots 808 discussed above in connection with FIGS. 8 and 10, the slots 1125 enable the connecting rod 810 to be coupled to the rotary motor 1123 on a first side of the nozzle plate 804 (and the actuator plate 1116) and to be coupled to the nozzle 802 on the second (opposite) side of the nozzle plate 804 (and the actuator plate 1116). More particularly, as most shown in FIG. 14A, the connecting rod 810 is coupled to the ball head 1212 of the nozzle 802 through an opening 1216 in the nozzle casing 1208. Further detail is shown in the enlarged drawing provided in FIG. 16. Additionally or alternatively, in some examples, the actuator plate 1116 includes an array of electromagnets 1502 aligned with corresponding ones of the nozzles 802 inside the nozzle plate assembly 1112. That is, in some examples, as shown and described further below in connection with FIG. 15, the electromagnets 1502 are aligned with (e.g., positioned underneath) corresponding ones of the rotary motors 1123.

In the illustrated example of FIG. 11, the jet impingement cooling system 1100 includes a controller circuitry 1124 (e.g., a microcontroller) mounted to the PCB 1102. In some examples, the controller circuitry 1124 corresponds to the controller circuitry 256 discussed above in connection with FIG. 2. That is, in some examples, the microcontroller is communicatively coupled to temperatures sensors within the IC package 702 to obtain and monitor temperature data indicative of the temperature profile of the IC package 702. Further, in some examples, the controller circuitry 1124 is communicatively coupled to the IC package 702 to obtain predictive data (e.g., workloads, scheduled tasks, etc.) of the current and/or future operations of the IC package 702 (e.g., the workloads being performed and/or to be performed by each of the tiles 704, 706, 708, 710). In some examples, the controller circuitry 1124 is communicatively coupled to the IC package 702 (and the associated temperature sensors of the package) through the PCB 1102. In some examples, the controller circuitry 1124 is also communicatively coupled to motors, actuators, and/or other mechanisms within and/or on the nozzle plate assembly 1112 that enable the nozzles 802 and/or nozzle plate 804 to be moved or adjusted. In some examples, the controller circuitry 1124 is communicatively coupled to these components via one or more wires extending from the controller circuitry 1124 to the nozzle plate assembly 1112.

FIG. 12A is an upward facing perspective view of the example nozzle enclosure 1118 of the nozzle plate assembly 1112 of FIG. 11. FIG. 12B is a downward facing perspective view of the example nozzle enclosure 1118 of the nozzle plate assembly 1112 of FIG. 11. As shown in the illustrated examples, the nozzle plate assembly 1112 includes the nozzle plate 804 discussed above in connection with FIGS. 8 and 10. As mentioned above, the nozzle plate 804 corresponds to the nozzle plate 212 of FIG. 2. Therefore, the corresponding description provided in connection with FIG. 2 applies equally to the nozzle plate 804 in FIG. 12. As shown in the illustrated example of FIG. 12A, the nozzle plate 804 supports an array of nozzles 802 that extend downwards from the nozzle plate 804 within the enclosure 1118 of the nozzle plate assembly 1112. In some examples, the enclosure 1118 is mounted to and/or positioned against the bolster retention plate 1106 when the jet impingement cooling system 1100 of FIG. 11 is assembled.

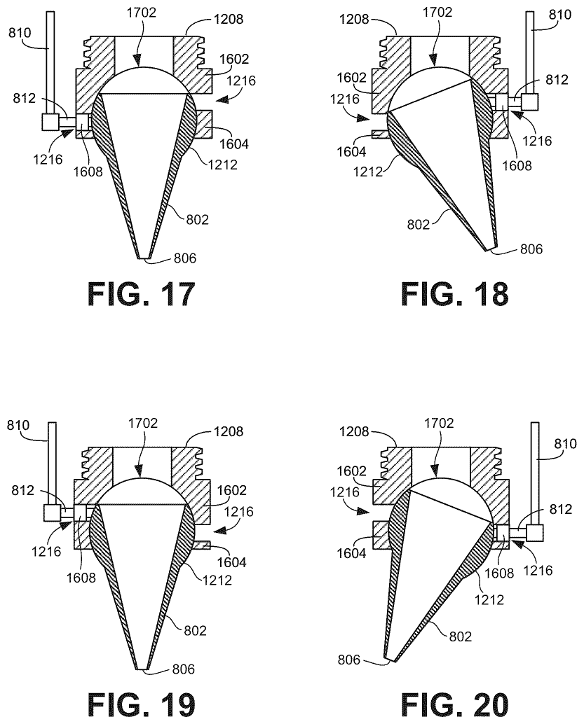

In the illustrated example, the nozzles 802 are coupled to the nozzle plate 804 by respective nozzle seat assemblies 1204. In some examples, each nozzle seat assembly 1204 includes a cylindrical armature 1206 and a nozzle casing 1208 (e.g., nozzle cage) disposed within the armature 1206. In some examples, the nozzle casing 1208 is threadedly coupled with the armature 1206. In other examples, the nozzle casing 1208 is coupled to the armature 1206 in any other suitable manner. In some examples, the nozzle casing 1208 is an integral extension of the armature 1206. As shown in FIG. 12A, the nozzles 802 include a first segment or portion 1210 that is tapered or cone-shaped. Thus, the first segment 1210 is also referred to herein as the nozzle cone. In some examples, the nozzle cone 1210 defines an internal, cone-shaped channel leading to the outlet 806 of the nozzle 802. The nozzle 802 also includes a second segment or portion 1212 that is generally spherical. In some examples, the spherical second segment 1212 of the nozzle 802 also defines a portion of the internal, cone-shaped channel (in addition to the nozzle cone 1210) as shown in FIGS. 17-20 discussed further below. In some examples, the spherical second segment 1212 also defines a ball head for the nozzle 802 that is captured and/or retained within a correspondingly dimensioned spherical cavity in the nozzle casing 1208. Thus, the second segment 1212 is also referred to herein as a ball head. The ball head 1212 of the nozzle 802 retained with the spherical cavity of the nozzle casing 1208 provides a gimballed connection that allows the nozzle 802 to rotate relative to the nozzle casing 1208 about all three axes in a coordinate system located at the center of the spherical ball head and spherical cavity. Further detail regarding the movement of the nozzles 802 relative to the casings 1208 is provided below in connection with FIGS. 16-24.

In the illustrated example of FIGS. 12A and 12B, and further shown in the cross-sectional side view of FIG. 14A, the nozzle plate 804 is integrally formed with and extends between inner walls of the nozzle enclosure 1118. Further, as shown in the illustrated example of FIGS. 12A and 14A, the nozzle plate 804 is spaced apart from a first (lower) surface 1203 of the enclosure to define a cavity or chamber 1205 into which the nozzles 802 extend. In this example, the lower surface 1203 of the enclosure includes one or more recesses 1207 that include one or more openings 1209 of associated channels 1402 within the walls of the nozzle enclosure 1118 that are in fluid communication with the fluid outlets 1122, as shown in FIG. 14A. In some examples, the recesses 1207 are positioned to align with (e.g., be in fluid communication with) corresponding recesses 1126 in the bolster retention plate 1106 (shown in FIG. 11). Thus, in some examples, after cooling fluid 213 impinges on the IC package 702 (shown in FIG. 11) to draw heat therefrom, the fluid is directed into the recesses 1207 (via the recesses 1126 in the bolster retention plate 1106), through the openings 1209, into the associated channels 1402, and out through the outlets 1122. Further, as shown in the illustrated example of FIG. 12B and 14A, the nozzle plate 804 is spaced apart from a second (upper) surface 1211 of the enclosure to define a second cavity or chamber 1213 on the opposite side of the nozzle plate 804 to the nozzles 802. In some examples, the walls of the nozzle enclosure 1118 surrounding the second cavity 1213 include one or more openings 1215 associated with channels 1404 within the walls of the nozzle enclosure 1118 in fluid communication with the fluid inlets 1120. FIG. 14B is a top view of the example nozzle enclosure 1118 cutaway along a plane passing through the openings 1215 to show an example arrangement of the channels 1404 disposed therein. That is, in some examples, the nozzle enclosure 1118 includes an integrated manifold of channels 1404 that direct cooling fluid 213 into the second cavity 1205 in a dispersed manner so that the fluid is provided substantially evenly to all of the nozzles 802. More particularly, as shown, the channels 1404 direct fluid (e.g., the cooling fluid 213) from the inlets 1120 to the openings 1215 and into the cavity 1213 above the nozzle assemblies 1204 to then pass through the nozzles 802 and onto the IC package 702. In this example, each of the two inlets 1120 is associated with a separate manifold of the channels 1404 within the walls of the nozzle enclosure 1118. In other examples, all of the channels 1404 may be in fluid communication. Further, in other examples, any other suitable arrangement of the channels and the associated openings 1215 may be implemented.

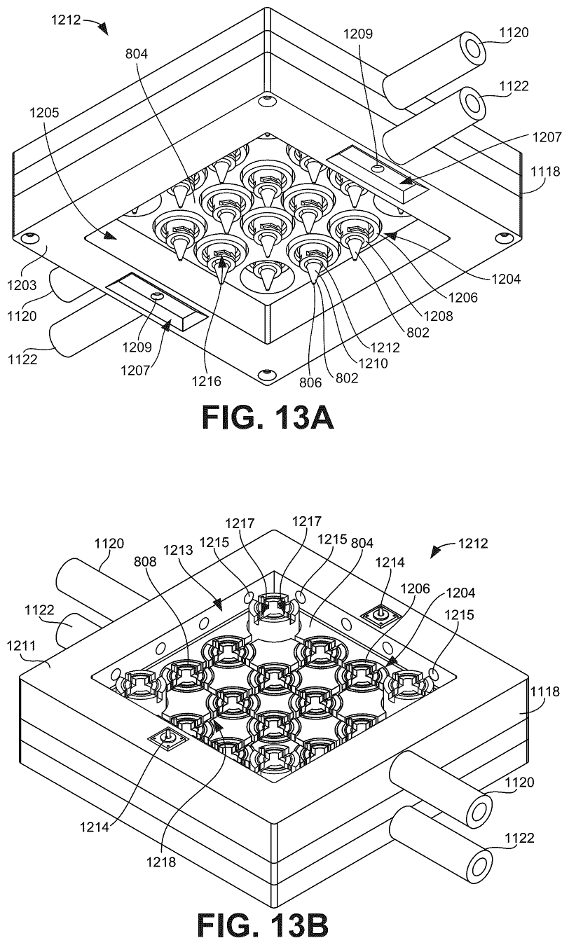

In some examples, the nozzle seat assemblies 1204 and the associated nozzles 802 can be selectively raised and lowered relative to the nozzle plate 804 as shown in the illustrated example of FIGS. 13A and 13B (collectively referred to herein as FIG. 13). Specifically, as shown in FIGS. 13A and 13B, the nozzle seat assemblies 1204 and the associated nozzles 802 in each of the four corners of the array of nozzles are lifted relative to the positions shown in FIGS. 12A and 12B. The particular nozzles 802 raised in the illustrated example is for purposes of explanation and any of the nozzles in any combination can be raised or lowered. That is, in some examples, each nozzle 802 can be selectively raised and lowered independent of the other nozzles 802. In some examples, the upper end of the armatures 1206 includes one or more notches 1217 that align with the openings 1215 in the walls of the nozzle enclosure 1118. As a result, when an armature 1206 is raised (as shown in FIG. 13B), the armature does not obstruct cooling fluid 213 entering the cavity 1213 from the openings 1215. Rather, the fluid 213 will pass through the notches 1217 so as to disperse through the cavity 1213 towards all the nozzles 802 in a substantially even manner. Further, in some examples, the nozzle plate 802 includes trenches 1218 that correspond to (e.g., align with) the notches 1217 in the armatures 1206 to define elongate channels interconnecting the different nozzle assemblies 1204 when the armatures 1206 are not raised up (e.g., are in the baseline position).

In some examples, the nozzle seat assemblies 1204 and the associated nozzles 802 are selectively raised and lowered by activating (e.g., energizing) and deactivating (e.g., deenergizing) an electromagnet. More particularly, in some examples, the armatures 1206 of the nozzle seat assemblies 1204 shown in the illustrated examples are created from and/or include a magnetic (e.g., ferrous) material such as iron or steel to react to magnetic forces selectively generated by an electromagnet 1502 (e.g., an electromagnetic coil) positioned above the armature 1206 within and/or on the actuator plate 1116 as shown in FIG. 15. More particularly, as shown in FIG. 15, an electromagnet 1502 is positioned on and/or or in the nozzle plate 804 within each of the C-shaped slots 1125 in the actuator plate 1116 discussed above in connection with FIG. 11. In some examples, when the electromagnet 1502 is in a first energy state (e.g., a deactivated state, a deenergized state, an off state), the armature 1206 is maintained in a default or baseline position protruding downwards from the nozzle plate as shown in FIGS. 12A and 12B. In some examples, when the electromagnet 1502 switches to a second energy state (e.g., an activated state, an energized state, an on state), the resulting magnetic force acts on the armature 1206 to pull it upwards towards the actuator plate 1116 (as with the corner nozzles 802 shown in FIGS. 13A and 13B). In some examples, the armature 1206 is magnetically pulled up to (e.g., abutting) the actuator plate 1116). In some examples, the armature 1206 is pulled into an opening in the actuator plate 1116. In some examples, the armature 1206 is pulled towards the actuator plate 1116 while remaining spaced therefrom. Inasmuch as the nozzle casing 1208 is coupled to the armature 1206, when the armature is raised by the electromagnet 1502, the nozzle casing 1208 (and the nozzle 802 retained therein) will also rise. As a result, the distance between the nozzle 802 and the IC package 702 on which the nozzle 802 is impinging cooling fluid is increased to affect the jet stream flow (e.g., increase and/or decrease the fluid velocity, increase or decrease cross flow, etc.). In some examples, the armature 1206 is spring loaded to urge the armature 1206 back into the default or baseline position when the electromagnet 1502 is switched back to the first (deenergized) state.

In some examples, the distance that the armature 1206 is raised from a baseline position when the electromagnet 1502 is energized (and the resulting distance of the nozzle 802 from the IC package 702 to be cooled) depends on the position of the actuator plate 1116 relative to the nozzle plate 804. That is, in some examples, the actuator plate 1116 can be selectively raised and lowered relative to nozzle plate 804 and, thus, relative to the underlying IC package 702. More particularly, in some examples, linear motors 1214 are operatively coupled to the nozzle enclosure 1118 to raise and lower the actuator plate 1116 relative to the enclosure 1118. In the illustrated example of FIGS. 12B, 13B, and 14B, there are two linear motors 1214. In other examples, only one linear motor 1214 is employed to move the nozzle plate 804. In other examples, more than two linear motors 1214 may be employed. In some examples, a gasket or other sealing member is positioned to extend between the actuator plate 116 and the enclosure 1118 to maintain a seal around the cavity 1213 regardless of the position of the actuator plate 116 relative to the enclosure 1118.

Further detail regarding the means for retaining and adjusting (e.g., gimballing) the nozzles 802 within a nozzle assembly 1204 is shown in the enlarged drawing provided in FIG. 16, in which the nozzle plate 804 omitted and the actuator plate 1116 is made see-through with edges represented by dashed lines. In this example, the armature 1206 is raised up (based on activation of the electromagnet 1502 discussed above in connection with FIG. 15) to be adjacent the underside of the actuator plate 1116. As shown in the illustrated example of FIG. 16, the opening 1216 in the nozzle casing 1208 is an elongate slot or track defined between an upper portion 1602 and a lower portion 1604 of the nozzle casing 1208. Accordingly, the opening 1216 is also referred to as a track that defines a path of the anchor 812 that coupled the connecting rod 810 to the ball head 1212 of the nozzle 802. In this example, the opening or track 1216 extends through the wall of the casing 1208 to expose the ball head 1212 of the nozzle 802. In some examples, the nozzle casing 1208 includes at least one rib 1606 connecting the upper and lower portions 1602, 1604 of the casing 1208. In some examples, the rib 1606 is aligned with the gap in the C-shaped slot 1125 (e.g., the solid portion that interconnects the portion of the actuator plate 1116 inside the C-shaped slot 1125 (that supports the motor 1123) and the rest of the actuator plate 1116). In some examples, the track 1216 in the nozzle casing 1208 extends circumferentially around the casing 1208 substantially the same extent as the C-shaped slot 1125. Thus, the track 1216 also has a C-shape. In this manner, as the rotary motor 1125 rotates about a central axis, the connecting rod 810 is able to travel along the C-shaped slot 1125 in the actuator plate 1116 (and the corresponding C-shapes slot 808 in the nozzle plate 804) and remain coupled to the nozzle 802 via the anchor 812 that extends through and travels along the C-shaped opening 1216 in the nozzle casing 1208. Furthermore, inasmuch as the anchor 812 physically couples the connecting rod 810 to the ball head 1212 of the nozzle 802, the nozzle 802 will also rotate with the rotary motor 1123.

In some examples, the anchor 812 supports a roller bearing 1608 situated within and rolls along the track 1216. As shown in the illustrated example, the track 1216 is an undulating track with a wavelike shape that includes one or more peaks and one or more troughs. The peaks are higher than the troughs. As a result, as the rotary motor 1123 rotates about a central axis to cause the roller bearing 1608 to travel along the track 1216 in the nozzle casing, the undulations in the track 1216 will cause the roller bearing 1608 to raise or lower relative to the bottom surface of the nozzle casing 1208. As such, the anchor 812, supporting the bearing 1608 and coupled to the nozzle 802 inside the nozzle casing 1208, will also raise or lower, thereby causing the nozzle 802 to tilt or rotate relative to a baseline orthogonal position. This process is made clearer by reference to FIGS. 17-20.

In particular, FIG. 17 is a cross-sectional view of an example nozzle 802 contained within an example nozzle casing 1208. As shown in the illustrated example, the nozzle 802 includes a spherical ball head 1212 that is captured within a spherical cavity 1702 to provide a gimballed connection enabling the nozzle 802 to rotate in any direction relative to the casing 1208. The opening or track 1216 extends around the ball head 1212 so as to expose the ball head 1212 on both sides of the drawing shown in FIG. 17 (e.g., 180 degrees apart). More particularly, in this example, the point along the track 1216 on the left side of FIG. 17 corresponds to a trough or low point of the track 1216. By contrast, the point along the track 1216 on the right side of FIG. 17 corresponds to a peak or high point of the track 1216. In the illustrated example of FIG. 17, the roller bearing 1608 is located at the low point of the track 1216 (left side in the drawing). However, as the connecting rod 810 is rotated or moved (by the rotary motor 1123) 180 degrees around the nozzle 802 (along the C-shaped slots 808, 1125 in the nozzle plate 804 and the actuator plate 1116), the roller bearing 1608 will follow the connecting rod 810 along the track 1216 to the point on the right side in FIG. 17. The final position of the roller bearing 1608 and connecting rod 810 is shown in FIG. 18. Thus, as the roller bearing 1608 is moved along the track 1216 from the position shown in FIG. 17 to the position shown in FIG. 18, the roller bearing 1608 moves from a low point on the track (FIG. 17) to a high point (FIG. 18). The rising of the roller bearing 1608 from FIG. 17 to FIG. 18 due to rotation of the motor 1123 of FIG. 16 results in the anchor 812 also rising. The raising of the anchor 812, in turn, raises the corresponding side of the ball head 1212 to which the anchor 812 is attached, thereby causing the nozzle 802 to rotate or tilt as shown in FIG. 18. In some examples, the anchor 812 is flexible and/or is coupled to the ball head 1212 of the nozzle 802 with a flexible joint to account for the rotation of the ball head 1212 relative to the anchor 812 that is held fixed within the track 1216 by the roller bearing 1608.

Thus, in some examples, when the roller bearing 1608 is located at a low point (e.g., a trough) in the track 1216, the nozzle 802 is in the baseline orthogonal position and as the roller bearing 1608 moves upward from the low point (e.g., towards a high point), the angle of tilt or rotation of the nozzle 802 increases. More particularly, the tip or end of the nozzle (e.g., at the outlet 806) will extend in a direction towards and/or underneath the location of the roller bearing 1608 and the connecting rod 810. In other examples, the orthogonal position of the nozzle 802 can be achieved when the roller bearing 1608 is at a high point (e.g., a peak) in the track 1216 with the nozzle becoming more tilted or angled as the roller bearing 1608 moves lower (e.g., towards a low point) as shown in FIGS. 19 and 20. Specifically, in FIG. 19, the roller bearing is at a high point along the track 1216 (on the left side of the drawing) with the nozzle 802 in a baseline orthogonal position. FIG. 20 shows the result after the roller bearing 1608 has moved (by the connecting rod 810 driven by the rotary motor 1123) to the opposite side of the casing 1208 associated with a low point of the track 1216. As shown in FIG. 20, the nozzle 802 is angled relative to the orthogonal position with the nozzle tip (at the outlet 806) extending in a direction opposite to or away from the location of the roller bearing 1608 and the connecting rod 810.

The illustrated examples of FIGS. 17-20 show low and high points of the track 1216 being 180 degrees apart. However, examples disclosed herein are not limited to such scenarios. In other examples, as shown in FIG. 16, the undulations of the track 1216 define successive peaks and troughs significantly closer together than 180 degrees. Further, in some examples, positions along the track 1216 that are 180 degrees apart may be at the same height (with intermediate high points and/or low points therebetween). In other examples, positions 180 degrees apart may be at any other height between the high and low points of the track 1216. Further, in some examples, the track 1216 can follow a different path other than wavelike undulations. For example, in some situations, the track 1216 may include extended regions at the high point, the low point, and/or at any intermediate point in between. Further, in some examples, there may be only one location on the track associated with the orthogonal position with all other points being at a different height so that all rotational positions of the roller bearing 1608 result in some degree of tilt or rotation relatively to the orthogonal position except for the one location associated with the orthogonal position. In some examples, the shape of the track 1216 can differ between different nozzle casings 1208 associated with different nozzles 802 depending on the location of the different nozzles 802 relative to the IC package 702 to be cooled. For instance, nozzles 802 located adjacent to the edge the IC package 702 will not need to be angled in a direction pointing away from the IC package 702. As such, the track 1216 in the nozzle casing 1208 for such a nozzle 802 may be constructed to be angled only in directions that point towards the IC package 702. Other suitable variations are also possible.

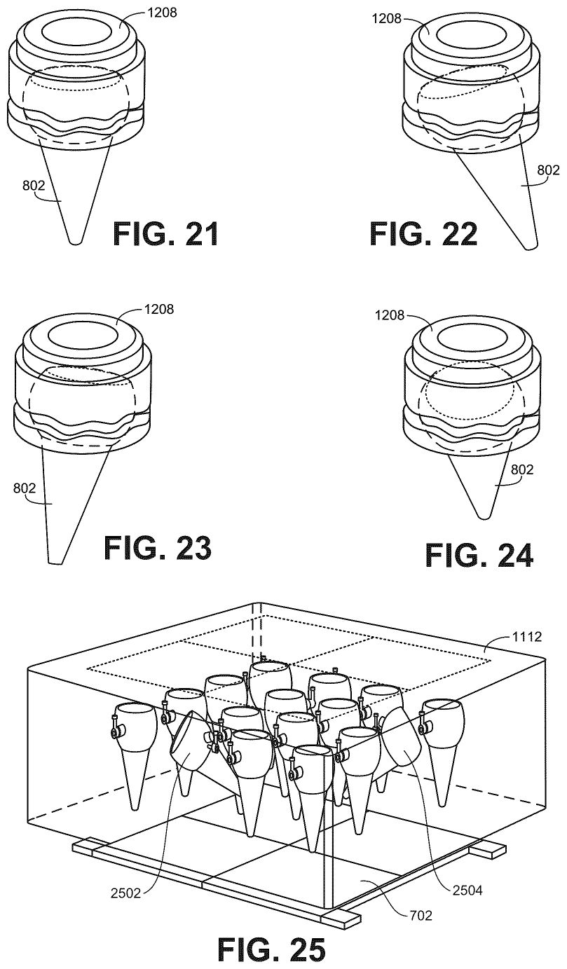

Based on the particular shape of the track 1216, as the roller bearing 1608 moves along the track, the height of the roller bearing 1608 and, thus, the rotation or tilt of the nozzle 802 can be controlled to point in any suitable direction to target any location across the surface of the IC package 702. FIGS. 21-24 are three-dimensional renderings of a nozzle 802 within a nozzle casing 1208 oriented in different directions. Specifically, FIG. 21 illustrates the nozzle 802 in the baseline orthogonal position with the end of the nozzle 802 pointing vertically down, FIG. 22 illustrates the end of the nozzle 802 angled towards the right, FIG. 23 illustrates the end of the nozzle 802 angled out of the page and to the left, and FIG. 24 illustrates the end of the nozzle 802 angled into the page and slightly to the right.

FIG. 25 illustrates the array of nozzles 802 within the nozzle plate assembly 1112 of FIG. 11 with the nozzle seat assemblies 1204 removed and the nozzle plate assembly 1112 represented as see-through for the sake of visibility of the internal components (e.g., the nozzles). As shown in FIG. 25, two different nozzles 2502, 2504 are angled in different directions towards a central area on the IC package 702 while all other nozzles are in the orthogonal position.

Returning to FIG. 16, inasmuch as the roller bearing 1608 raises and lowers as it moves along the track 1216 in the nozzle casing 1208, which remains at a fixed spatial distance relative to the rotary motor 1123, the roller bearing 1608 also raises and lower relative to the rotary motor 1123. In some examples, to account for this change in spatial relationship between the roller bearing 1608 and the rotary motor 1123, the connecting rod 810 extending between the roller bearing 1608 (and the anchor 812) and the motor 1123 is a telescopic rod with a first segment 1610 that nests or extends inside a second segment 1612 as shown in FIG. 16. In some examples, the second segment 1612 nests or extends inside the first segment 1610. In some examples, the extendible and collapsible nature of the connecting rod 810 also accounts for changes in the relative positions of the nozzle casing 1208 and the rotary motor 1123 when the nozzle seat assembly 1204 is raised or lowered in response to a magnetic force from the electromagnet 1502 acting on the armature 1206 being applied or removed as discussed above. In some examples, as represented in FIGS. 12A, 13A, and 14A, the connecting rod 810 extends between the nozzles 802 and the rotary motor 1123 through the interior of the cylindrical armature 1206. In other examples, as represented in FIG. 16, the connecting rod 810 extends between the nozzles 802 along an exterior of the armature 1206.

In some examples, the adjustable (e.g., collapsible and extendible) length of the connecting rod 810 is controlled by a linear actuator operatively coupled to the rod 810. In some such examples, the different heights along the track 1216 are unnecessary because the linear actuator can cause the rod 810 to lengthen or shorten, thereby raising or lowering the anchor 812 (coupled to the end of the rod 810) to cause the nozzle 802 to be angled or tilt about the gimballed connection defined by the ball head 1212 within the nozzle casing 1208.

FIG. 26 is a block diagram of an example implementation of controller circuitry 2600 corresponding to the controller circuitry 256 of FIG. 2 and/or the controller circuitry 1124 of FIG. 11 to dynamically adjust the position of nozzles in a jet impingement cooling system based on detected hotspots (including actual (current) hotspots as well as predicted (future) hotspots). The controller circuitry 2600 of FIG. 26 may be instantiated (e.g., creating an instance of, bring into being for any length of time, materialize, implement, etc.) by programmable circuitry such as a Central Processor Unit (CPU) executing first instructions. Additionally or alternatively, the controller circuitry 2600 of FIG. 2 may be instantiated (e.g., creating an instance of, bring into being for any length of time, materialize, implement, etc.) by (i) an Application Specific Integrated Circuit (ASIC) and/or (ii) a Field Programmable Gate Array (FPGA) structured and/or configured in response to execution of second instructions to perform operations corresponding to the first instructions. It should be understood that some or all of the circuitry of FIG. 26 may, thus, be instantiated at the same or different times. Some or all of the circuitry of FIG. 26 may be instantiated, for example, in one or more threads executing concurrently on hardware and/or in series on hardware. Moreover, in some examples, some or all of the circuitry of FIG. 26 may be implemented by microprocessor circuitry executing instructions and/or FPGA circuitry performing operations to implement one or more virtual machines and/or containers.

As shown in FIG. 26, the example controller circuitry 2600 includes example interface circuitry 2602, example temperature data analyzing circuitry 2604, example predictive data analyzing circuitry 2606, example jet vector determining circuitry 2608, example height determining circuitry 2610, example actuator controller circuitry 2612, and example memory 2614.

The example controller circuitry 2600 of FIG. 26 is provided with the example interface circuitry 2602 to communicate with other components in the example jet impingement cooling system 200 of FIGS. 2 and 3 (and/or the jet impingement cooling system 1100 of FIG. 11). More particularly, in some examples, the interface circuitry 2602 communicates with the temperature sensors 258 to obtain current (e.g., substantially real-time) temperature measurements of an IC package being cooled by the cooling system 200, 1100.

Further, in some examples, the interface circuitry 2602 communicates with the IC package (e.g., the IC package 210 of FIGS. 2 and 3, the IC package 400 of FIG. 4, the IC package 702 of FIGS. 7-25) to obtain predictive data about the operation of the IC package. As explained above, predictive data is data that indicates future operations of the IC package that can be used to predict areas of the IC package that will dissipate power when the operations are commenced and performed. In some examples, the predictive data includes workload data indicative of imminent workloads of the IC package. In some examples, the predictive data includes schedule data from a task scheduler associated with the IC package that indicates tasks scheduled for implementation by the IC package. In some examples, the predictive data may indicate the particular portion or region of an IC package that is to perform a given task or operation. For instance, the predictive data can identify a particular tile (e.g., a particular core) and/or a particular region of a monolithic semiconductor die where the relevant circuitry is located to identify the area where heat is to be produced once the imminent and/or scheduled task is initiated. In some examples, the predictive data includes machine learning output data generated by a machine learning model that has been trained on historical data including job placement of workloads and associated hotspots and/or temperature profiles resulting from such job placements. In some examples, the machine learning model may be executed by the controller circuitry 2600. In other examples, the machine learning model is executed by an external system that communicates with the controller circuitry 2600 via the interface circuitry 2602.

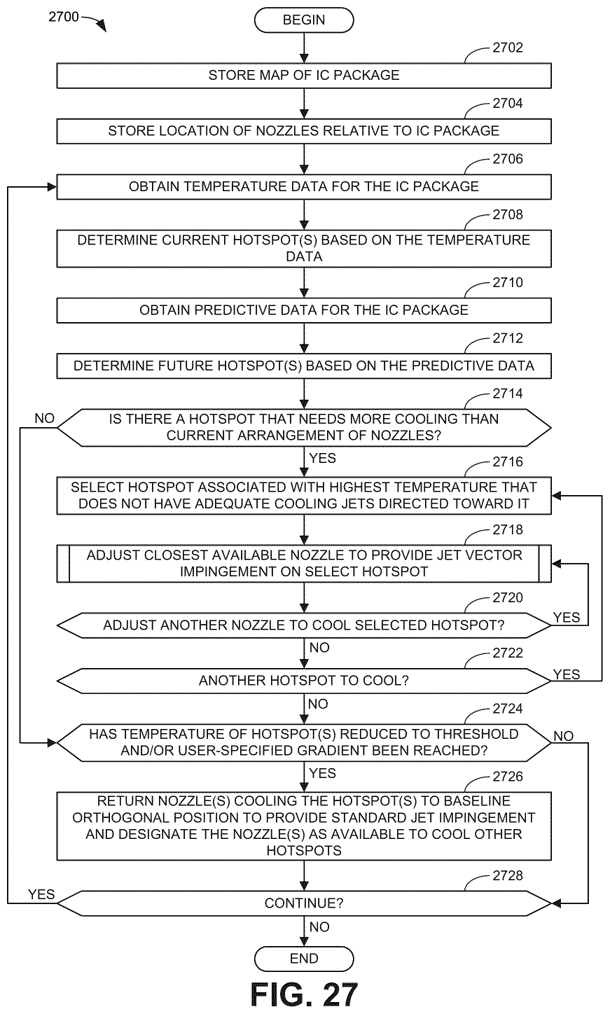

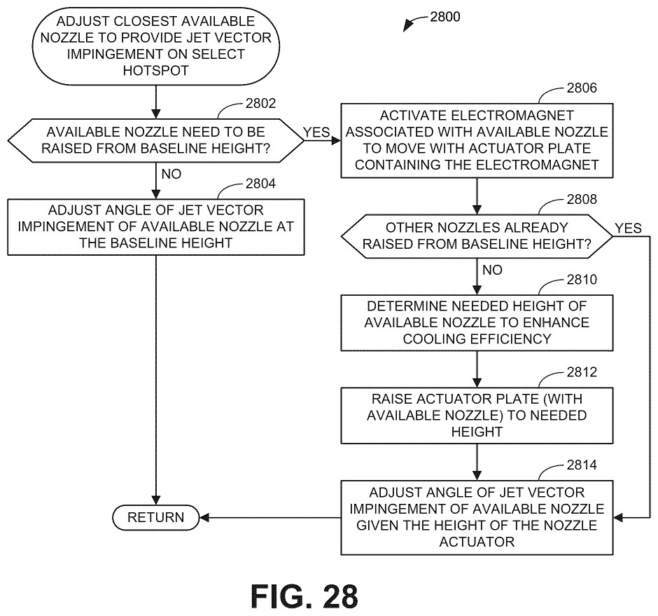

Additionally, in some examples, the interface circuitry 2602 communicates with (e.g., sends command signals to and/or receives feedback from) actuators in the jet impingement cooling system 200, 1100 to cause adjustments to the position and/or orientation of the nozzles 802. In some examples, the actuators include (1) the linear motors 1214 used to selectively raise or lower the height of the nozzle plate 804 relative to the underlying IC package, (2) the electromagnets 1502 used to raise or lower the armatures 1206 (along with the nozzle casings 1208 and the associated nozzles 802), (3) the rotary motors 1123 used to rotate the nozzles 802 via the connecting rods 810, and/or (4) linear actuators used to selectively increase and/or decrease the length of the connecting rods 810. In some examples, the interface circuitry 2602 is instantiated by programmable circuitry executing interface instructions and/or configured to perform operations such as those represented by the flowchart(s) of FIGS. 27 and 28.

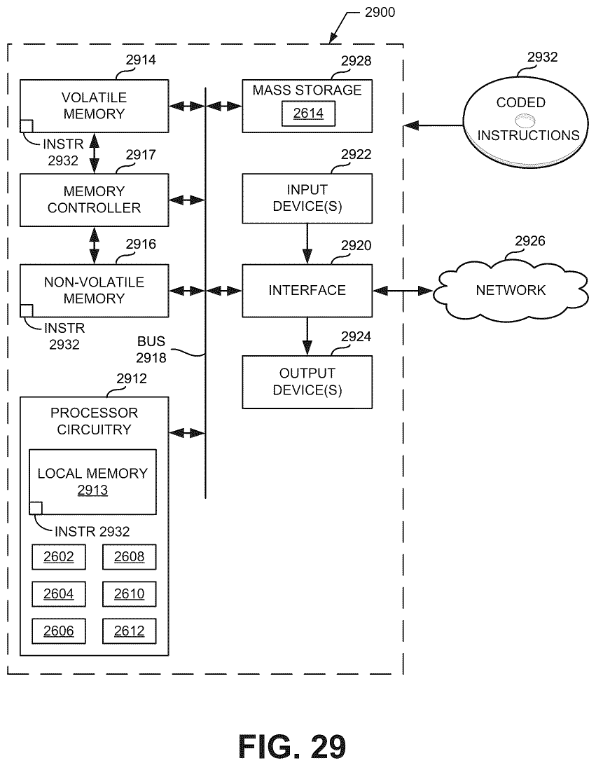

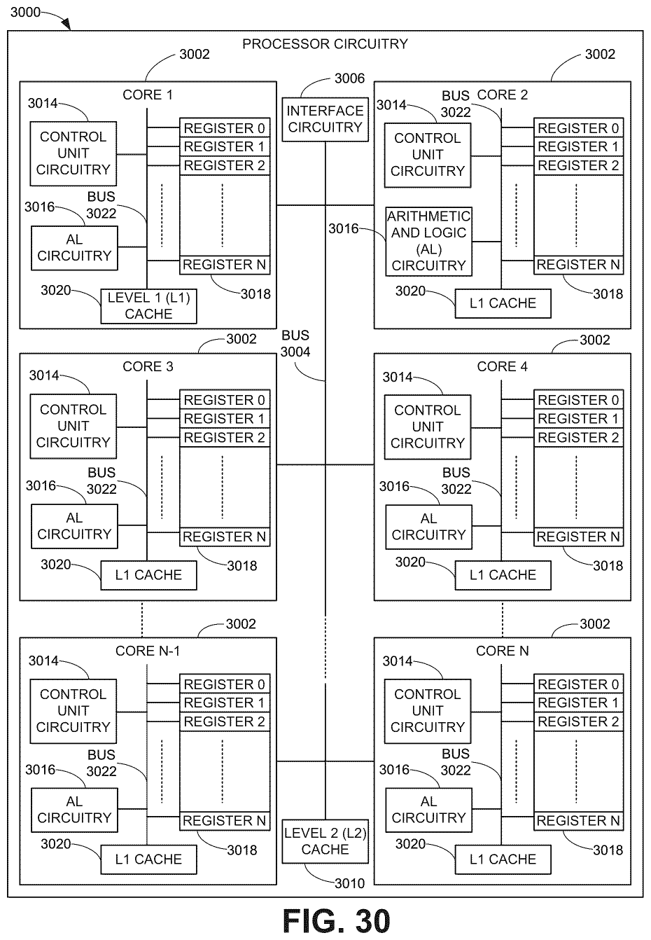

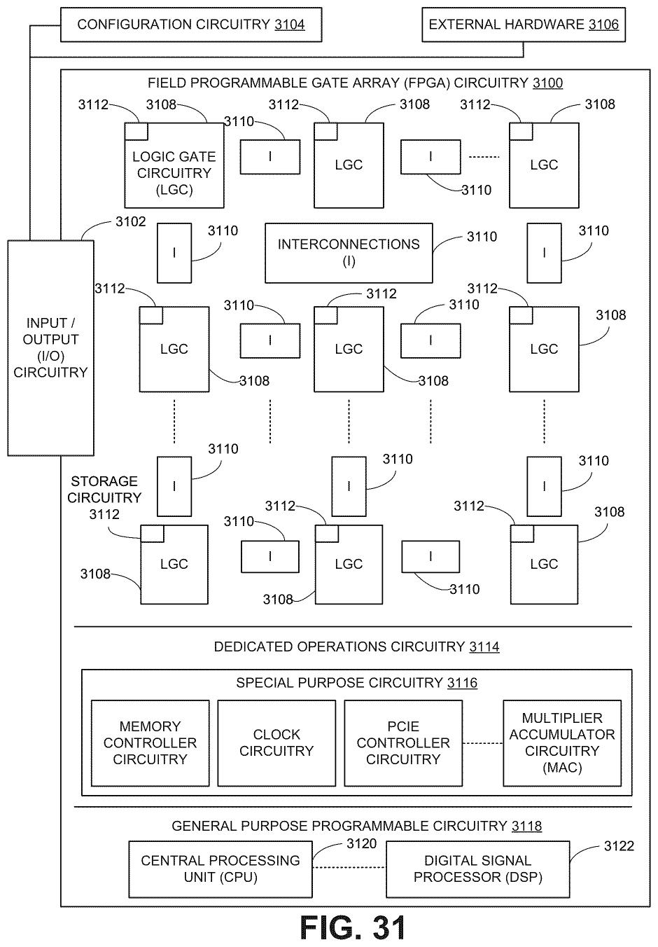

In some examples, the controller circuitry 2600 includes means for interfacing with external components. For example, the means for interfacing may be implemented by interface circuitry 2602. In some examples, the interface circuitry 2602 may be instantiated by programmable circuitry such as the example programmable circuitry 2912 of FIG. 29. For instance, the interface circuitry 2602 may be instantiated by the example microprocessor 3000 of FIG. 30 executing machine executable instructions such as those implemented by at least blocks 2706, 2710 of FIG. 27. In some examples, the interface circuitry 2602 may be instantiated by hardware logic circuitry, which may be implemented by an ASIC, XPU, or the FPGA circuitry 3100 of FIG. 31 configured and/or structured to perform operations corresponding to the machine readable instructions. Additionally or alternatively, the interface circuitry 2602 may be instantiated by any other combination of hardware, software, and/or firmware. For example, the interface circuitry 2602 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The example controller circuitry 2600 of FIG. 26 is provided with the example temperature data analyzing circuitry 2604 to analyze the temperature data obtained from the temperature sensors 258 via the interface circuitry 2602. In some examples, the temperature data analyzing circuitry 2604 generates a temperature profile for the IC package to identify the presence and location of actual hotspots and/or temperature gradients across the IC package. In some examples, the locations of hotspots are based on known positions (e.g., XY position) of the temperature sensors 258 within the IC package. In some examples, the known positions of the temperature sensors 258 are stored in the example memory 2614. In some examples, the temperature data analyzing circuitry 2604 sorts and/or orders the temperature data from each of the different temperature sensors 258 from highest temperature to lowest temperature to define an order in which nozzle adjustment decisions are to be made as discussed further below. In some examples, the temperature data analyzing circuitry 2604 is instantiated by programmable circuitry executing temperature data analyzing instructions and/or configured to perform operations such as those represented by the flowchart(s) of FIGS. 27 and 28.

In some examples, the controller circuitry 2600 includes means for analyzing temperature data. For example, the means for determining may be implemented by temperature data analyzing circuitry 2604. In some examples, the temperature data analyzing circuitry 2604 may be instantiated by programmable circuitry such as the example programmable circuitry 2912 of FIG. 29. For instance, the temperature data analyzing circuitry 2604 may be instantiated by the example microprocessor 3000 of FIG. 30 executing machine executable instructions such as those implemented by at least blocks 2708, 2724 of FIG. 27. In some examples, the temperature data analyzing circuitry 2604 may be instantiated by hardware logic circuitry, which may be implemented by an ASIC, XPU, or the FPGA circuitry 3100 of FIG. 31 configured and/or structured to perform operations corresponding to the machine readable instructions. Additionally or alternatively, the temperature data analyzing circuitry 2604 may be instantiated by any other combination of hardware, software, and/or firmware. For example, the temperature data analyzing circuitry 2604 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The example controller circuitry 2600 of FIG. 26 is provided with the example predictive data analyzing circuitry 2606 to analyze the predictive data obtained via the interface circuitry 2602. More particularly, in some examples, the predictive data analyzing circuitry 2606 analyzes the predictive data to determine or predict future hotspots. That is, in some examples, the predictive data analyzing circuitry 2606 determines where workloads, tasks, and/or operations are about to commence to identify where power is to be dissipated giving rise to the possibility of hotspots arising from the additional heat being produced. As discussed above and further below, in some examples, the nozzles 802 are moved to cause jet vectored streams of cooling fluid onto such locations before the workloads are initiated. In this manner, the nozzles 802 preemptively cool the identified locations to reduce and/or entirely arrest a Tⱼ-rise resulting once the scheduled workload is initiated. In some examples, the predictive data analyzing circuitry 2606 sorts and/or orders the future hotspots according to a degree of criticality and/or expected temperature to be reached based on the nature and/or duration of a given workload assigned to a particular area (e.g., a particular core) of an IC package. In some examples, the ordering of the future hotspots is used to define an order in which nozzle adjustment decisions are to be made as discussed further below. In some examples, the predictive data analyzing circuitry 2606 is instantiated by programmable circuitry executing predictive data analyzing instructions and/or configured to perform operations such as those represented by the flowchart(s) of FIGS. 27 and 28.

In some examples, the controller circuitry 2600 includes means for analyzing predictive data. For example, the means for determining may be implemented by predictive data analyzing circuitry 2606. In some examples, the predictive data analyzing circuitry 2606 may be instantiated by programmable circuitry such as the example programmable circuitry 2912 of FIG. 29. For instance, the predictive data analyzing circuitry 2606 may be instantiated by the example microprocessor 3000 of FIG. 30 executing machine executable instructions such as those implemented by at least block 2712 of FIG. 27. In some examples, the predictive data analyzing circuitry 2606 may be instantiated by hardware logic circuitry, which may be implemented by an ASIC, XPU, or the FPGA circuitry 3100 of FIG. 31 configured and/or structured to perform operations corresponding to the machine readable instructions. Additionally or alternatively, the predictive data analyzing circuitry 2606 may be instantiated by any other combination of hardware, software, and/or firmware. For example, the predictive data analyzing circuitry 2606 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the predictive data analyzing circuitry 2606 is omitted. In such examples, adjustments to the position and/or orientation of the nozzles 802 are based on the temperature data analyzed by the temperature data analyzing circuitry 2604. In other examples, the temperature data analyzing circuitry 2604 is omitted. In such examples, adjustments to the position and/or orientation of the nozzles 802 are based on the predictive data analyzed by the predictive data analyzing circuitry 2606.

The example controller circuitry 2600 of FIG. 26 is provided with the example jet vector determining circuitry 2608 to determine the angle or direction in which a nozzle 802 is to point to increase (e.g., maximize) heat dissipation. That is, the example jet vector determining circuitry 2608 determines the jet vectored position for each nozzle 802. In some examples, the nozzles 802 are jet vectored to a particular position in a sequence that is driven by the ordering of the hotspots determined by the temperature data analyzing circuitry 2604 and/or the predictive data analyzing circuitry 2606 as mentioned above. Specifically, in some examples, the most critical hotspots (e.g., actual hotspots associated with the highest temperature and/or future hotspots associated with the highest expected temperature or thermal dissipation) are assigned the closest nozzle(s) 802 so that the angle of impingement is as close to 90 degrees as possible, to reduce the need for gimballing of the nozzles and to improve the cooling efficiency of the resulting fluid impingement. Accordingly, in some examples, the jet vector determining circuitry 2608 determines which nozzle 802 is closest to a given hotspot. In some examples, the jet vector determining circuitry 2608 makes this determination based on position information for each of the nozzles 802 stored in the example memory 2614.

In some examples, depending on the criticality of the hotspot, the jet vector determining circuitry 2608 may select more than one nozzle 802 to be jet vectored to a given hotspot. Once an adequate number of nozzles 802 are assigned to the most critical hotspot, the next most critical hotspot is addressed with the next closest nozzle (which may not be the closest nozzle if the closest nozzle is already designated to cool a more critical hotspot). The process continues until every identified hotspot is being cooled by an adequate number of nozzles. In some examples, if some nozzles are not needed to cool a particular hotspot, the jet vector determining circuitry 2608 designates those nozzles to be oriented to the baseline orthogonal position and made available to be jet vectored towards hotspots that may subsequently arise. In some examples, the jet vector determining circuitry 2608 is instantiated by programmable circuitry executing jet vector determining instructions and/or configured to perform operations such as those represented by the flowchart(s) of FIGS. 27 and 28.

In some examples, the controller circuitry 2600 includes means for determining the position, orientation, and/or jet vectoring of a nozzle. For example, the means for determining may be implemented by jet vector determining circuitry 2608. In some examples, the jet vector determining circuitry 2608 may be instantiated by programmable circuitry such as the example programmable circuitry 2912 of FIG. 29. For instance, the jet vector determining circuitry 2608 may be instantiated by the example microprocessor 3000 of FIG. 30 executing machine executable instructions such as those implemented by at least blocks 2714, 2716, 2718, 2720, 2722, 2726, 2728 of FIG. 27. In some examples, the jet vector determining circuitry 2608 may be instantiated by hardware logic circuitry, which may be implemented by an ASIC, XPU, or the FPGA circuitry 3100 of FIG. 31 configured and/or structured to perform operations corresponding to the machine readable instructions. Additionally or alternatively, the jet vector determining circuitry 2608 may be instantiated by any other combination of hardware, software, and/or firmware. For example, the jet vector determining circuitry 2608 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The example controller circuitry 2600 of FIG. 26 is provided with the example height determining circuitry 2610 to determine the height at which a nozzle is to be positioned relative to an IC package. In some examples, these determinations are made in conjunction with the jet vectored positions for the nozzles determined by the jet vector determining circuitry 2608 to facilitate a particular nozzle to reach a particular location on the IC package. Accordingly, in some examples, the jet vector determining circuitry 2608 and the height determining circuitry 2610 may be integrated and/or implemented in combination. In some examples, the determination of a height for a given nozzle is based on effects of cross flow associated with the height. In some examples, the height of a nozzle 802 is selectively controlled between a baseline position and an elevated position associated with the height of the nozzle plate 804. Accordingly, in some examples, the height determining circuitry 2610 determines the height at which the nozzle plate 804 is to be positioned. Further, in some examples, the height determining circuitry 2610 determines which of the nozzles 802 are to be raised to the height of the nozzle plate 804 and which of the nozzles 802 are to be maintained at the default baseline height. In some examples, the height determining circuitry 2610 is instantiated by programmable circuitry executing height determining instructions and/or configured to perform operations such as those represented by the flowchart(s) of FIGS. 27 and 28.

In some examples, the controller circuitry 2600 includes means for determining a height of a nozzle relative to an IC package. For example, the means for determining may be implemented by height determining circuitry 2610. In some examples, the height determining circuitry 2610 may be instantiated by programmable circuitry such as the example programmable circuitry 2912 of FIG. 29. For instance, the height determining circuitry 2610 may be instantiated by the example microprocessor 3000 of FIG. 30 executing machine executable instructions such as those implemented by at least block 2718 of FIG. 27 and blocks 2802, 2808, 2810 of FIG. 28. In some examples, the height determining circuitry 2610 may be instantiated by hardware logic circuitry, which may be implemented by an ASIC, XPU, or the FPGA circuitry 3100 of FIG. 31 configured and/or structured to perform operations corresponding to the machine readable instructions. Additionally or alternatively, the height determining circuitry 2610 may be instantiated by any other combination of hardware, software, and/or firmware. For example, the height determining circuitry 2610 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The example controller circuitry 2600 of FIG. 26 is provided with the example actuator controller circuitry 2612 to send commands and/or instructions that control the operation of the actuators that cause adjustments and/or movement of the nozzles 802 and/or the nozzle plate 804. In some examples, the commands and/or instructions are based on the jet vector positions for the nozzles 802 determined by the jet vector determining circuitry 2608 and based on the designated height for the nozzle plate 804 determined by the height determining circuitry 2610. In some examples, the actuator controller circuitry 2612 is instantiated by programmable circuitry executing actuator controller instructions and/or configured to perform operations such as those represented by the flowchart(s) of FIGS. 27 and 28.

In some examples, the controller circuitry 2600 includes means for controlling adjustments to a position and/or orientation of a nozzle. For example, the means for controlling may be implemented by actuator controller circuitry 2612. In some examples, the actuator controller circuitry 2612 may be instantiated by programmable circuitry such as the example programmable circuitry 2912 of FIG. 29. For instance, the actuator controller circuitry 2612 may be instantiated by the example microprocessor 3000 of FIG. 30 executing machine executable instructions such as those implemented by at least blocks 2718, 2726 of FIG. 27 and blocks 2804, 2806, 2812, 2814 of FIG. 28. In some examples, the actuator controller circuitry 2612 may be instantiated by hardware logic circuitry, which may be implemented by an ASIC, XPU, or the FPGA circuitry 3100 of FIG. 31 configured and/or structured to perform operations corresponding to the machine readable instructions. Additionally or alternatively, the actuator controller circuitry 2612 may be instantiated by any other combination of hardware, software, and/or firmware. For example, the actuator controller circuitry 2612 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

While an example manner of implementing the controller circuitry 256 of FIG. 2 and the controller circuitry 1124 of FIG. 11 is illustrated in FIG. 26, one or more of the elements, processes, and/or devices illustrated in FIG. 26 may be combined, divided, re-arranged, omitted, eliminated, and/or implemented in any other way. Further, the example interface circuitry 2602, the example temperature data analyzing circuitry 2604, the example predictive data analyzing circuitry 2606, the example jet vector determining circuitry 2608, the example height determining circuitry 2610, the example actuator controller circuitry 2612, the example memory 2614, and/or, more generally, the example controller circuitry 2600 of FIG. 26, may be implemented by hardware alone or by hardware in combination with software and/or firmware. Thus, for example, any of the example interface circuitry 2602, the example temperature data analyzing circuitry 2604, the example predictive data analyzing circuitry 2606, the example jet vector determining circuitry 2608, the example height determining circuitry 2610, the example actuator controller circuitry 2612, the example memory 2614, and/or, more generally, the example controller circuitry 2600, could be implemented by programmable circuitry in combination with machine readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), and/or field programmable logic device(s) (FPLD(s)) such as FPGAs. Further still, the example controller circuitry 2600 of FIG. 26 may include one or more elements, processes, and/or devices in addition to, or instead of, those illustrated in FIG. 26, and/or may include more than one of any or all of the illustrated elements, processes and devices.

Flowchart(s) representative of example machine readable instructions, which may be executed by programmable circuitry to implement and/or instantiate the controller circuitry 2600 of FIG. 26 and/or representative of example operations which may be performed by programmable circuitry to implement and/or instantiate the controller circuitry 2600 of FIG. 26, are shown in FIGS. 27 and 28. The machine readable instructions may be one or more executable programs or portion(s) of one or more executable programs for execution by programmable circuitry such as the programmable circuitry 2912 shown in the example processor platform 2900 discussed below in connection with FIG. 29 and/or may be one or more function(s) or portion(s) of functions to be performed by the example programmable circuitry (e.g., an FPGA) discussed below in connection with FIGS. 30 and/or 31. In some examples, the machine readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer readable and/or machine readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer readable and/or machine readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIGS. 27 and 28, many other methods of implementing the example controller circuitry 2600 may alternatively be used. For example, the order of execution of the blocks of the flowchart(s) may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). For example, the programmable circuitry may be a CPU and/or an FPGA located in the same package (e.g., the same integrated circuit (IC) package or in two or more separate housings), one or more processors in a single machine, multiple processors distributed across multiple servers of a server rack, multiple processors distributed across one or more server racks, etc., and/or any combination(s) thereof.

The machine readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine executable instructions. For example, the machine readable instructions may be fragmented and stored on one or more storage devices, disks and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable, computer readable and/or machine readable media, as used herein, may include instructions and/or program(s) regardless of the particular format or state of the machine readable instructions and/or program(s).

The machine readable instructions described herein can be represented by any past, present, or future instruction language, scripting language, programming language, etc. For example, the machine readable instructions may be represented using any of the following languages: C, C++, Java, C#, Perl, Python, JavaScript, HyperText Markup Language (HTML), Structured Query Language (SQL), Swift, etc.

As mentioned above, the example operations of FIGS. 27 and 28 may be implemented using executable instructions (e.g., computer readable and/or machine readable instructions) stored on one or more non-transitory computer readable and/or machine readable media. As used herein, the terms non-transitory computer readable medium, non-transitory computer readable storage medium, non-transitory machine readable medium, and/or non-transitory machine readable storage medium are expressly defined to include any type of computer readable storage device and/or storage disk and to exclude propagating signals and to exclude transmission media. Examples of such non-transitory computer readable medium, non-transitory computer readable storage medium, non-transitory machine readable medium, and/or non-transitory machine readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer readable storage device” and “non-transitory machine readable storage device” are defined to include any physical (mechanical, magnetic and/or electrical) hardware to retain information for a time period, but to exclude propagating signals and to exclude transmission media. Examples of non-transitory computer readable storage devices and/or non-transitory machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer-readable instructions, machine-readable instructions, etc.

FIG. 27 is a flowchart representative of example machine readable instructions and/or example operations 2700 that may be executed, instantiated, and/or performed by programmable circuitry to adjust the position and/or orientation of nozzles in a jet impingement cooling system (e.g., the jet impingement cooling system 200, 1100 of FIGS. 2 and/or 11) to mitigate hotspots. The example machine-readable instructions and/or the example operations 2700 of FIG. 27 begin at block 2702, where the example memory 2614 stores a map of an IC package (e.g., the IC package 210, the IC package 400, the IC package 702, etc.). In some examples, the map includes information about the location of all temperature sensors within the IC package. At block 2704, the example memory 2614 stores the location of nozzles 802 relative to the IC package.

At block 2706, the example interface circuitry 2602 obtains temperature data for the IC package. In some examples, this is obtained from temperature sensors 258 in or on the IC package. At block 2708, the example temperature data analyzing circuitry 2604 determines current hotspot(s) based on the temperature data. In some examples, this is based on direct measurements of temperature (from the temperature sensors 258). In some examples, this is based on comparisons or differentials between two different locations on the IC package. In some examples, the determination of current (actual) hotspots includes a determination of the presence of current hotspots as well as the location of the current hotspots.

At block 2710, the example interface circuitry 2602 obtains predictive data for the IC package. In some examples, this corresponds to imminent workloads and/or scheduled tasks for the IC package. In some examples, this is based on an output of a machine learning model analyzing job placement and current temperatures of the IC package. At block 2712, the example predictive data analyzing circuitry 2606 determines future (e.g., potential) hotspot(s) based on the predictive data. In some examples, the determination of future hotspots includes a determination of the possibility of actual hotspots arising based on future workloads to be initiated in the IC package as well as the location of the hotspots.

In some examples, only the temperature data is considered. In some such examples, blocks 2710 and 2712 may be omitted. In some examples, only the predictive data is considered. In some such examples, blocks 2706, 2708 may be omitted.

At block 2714, the example jet vector determining circuitry 2608 determines whether there is a hotspot that needs more cooling than the current arrangement of nozzles 802. The hotspots considered at this block include both current (actual) hotspots as well as future (potential) hotspots. If no hotspots need more cooling (e.g., the nozzles 802 are already in position and providing impinging fluid onto the relevant locations), then control advances block 2724. If the current arrangement of nozzles 802 is not adequate to cool the identified hotspots (e.g., there has been a change in the hotspots based on the temperature data and/or the predictive data), control advances to block 2716.

At block 2716, the example jet vector determining circuitry 2608 selects a hotspot associated with highest temperature that does not have adequate cooling jets directed toward it. That is, the example jet vector determining circuitry 2608 identifies the most critical hotspot. At block 2718, the controller circuitry 2600 (e.g., including the jet vector determining circuitry 2608, the height determining circuitry 2610, and/or the actuator controller circuitry 2612) adjust the closest available nozzle 802 to provide jet vector impingement on the selected hotspot. As used in this context, the closest available nozzle 802 is the closest nozzle 802 that has not already been designated for and adjusted to jet vector impinge on a different hotspot. Further details regarding the implementation of block 2718 are provided below in connection with FIG. 28.

At block 2720, the example jet vector determining circuitry 2608 determines whether to adjust another nozzle 802 to cool the selected hotspot. If so, control returns to block 2718. Otherwise, control advances to block 2722 where the example jet vector determining circuitry 2608 determines whether there is another hotspot to cool. If so, control returns to block 2716. Otherwise, control advances to block 2724.

At block 2724, the temperature data analyzing circuitry 2604 determines whether the temperature of one or more of the hotspot(s) has reduced to a threshold and/or whether a user-specified temperature gradient has been reached. If not, the cooling of the hotspots needs to continue. Accordingly, control advances to block 2728, where the controller circuitry 2600 (e.g., via the jet vector determining circuitry 2608) determines to continue the process and control returns to block 2706 to collect updated temperature data (block 2706) and updated predictive data (block 2710). In this manner, the example program of FIG. 27 implements a closed loop algorithm with substantially real-time feedback that enables dynamic adjustments to the position and orientations of the nozzles 802 as appropriate to improve the cooling efficiency of the system. Returning to block 2724, if the temperature data analyzing circuitry 2604 determines that the temperature of one or more of the hotspot(s) has reduced to the threshold and/or that the user-specified temperature gradient has been reached, control advances to block 2726.

At block 2726, the example actuator controller circuitry 2612 returns the nozzle(s) 802 cooling the hotspot(s) to a baseline orthogonal position to provide standard jet impingement and the jet vector determining circuitry 2608 designates the nozzle(s) 802 as available to cool other hotspots. Thereafter, control advances to block 2728 to determine whether to continue the process. If not, the example process of FIG. 27 ends.

FIG. 28 is a flowchart representative of example machine readable instructions and/or example operations 2800 that may be executed, instantiated, and/or performed by programmable circuitry to implement block 2718 of FIG. 27 to adjust the closest available nozzle 802 to provide jet vector impingement on a select hotspot. The example machine-readable instructions and/or the example operations 2800 of FIG. 28 begin at block 2802, where the example height determining circuitry 2610 determines whether the available nozzle 802 needs to be raised from a baseline height. If not, control advances to block 2804 where the example actuator controller circuitry 2612 adjusts the angle of jet vector impingement of the available nozzle 802 at the baseline height. Thereafter, the example process of FIG. 28 ends and returns to complete the process of FIG. 27. In some examples, the jet vector impingement is adjusted by causing rotation of an associated rotary motor 1123 that results in rotation of the nozzle 802 due to a connecting rod 810 coupled between the motor 1123 and the nozzle 802.

Returning to block 2802, if the example height determining circuitry 2610 determines that the available nozzle 802 needs to be raised from a baseline height, control advances to block 2806. At block 2806, the example actuator circuitry 2612 activates an electromagnet 1502 associated with the available nozzle 802 to move with an actuator plate 1116 containing the electromagnet 1502. Thereafter, at block 2808, the example height determining circuitry 2610 determines whether there are other nozzles 802 already raised from baseline height. If not, control advances to block 2810 where the example height determining circuitry 2610 determines the needed height of the available nozzle 802 to enhance cooling efficiency. In some examples, this is based on adjusting the reach of the nozzle jet stream at a given angle of tilt. In some examples, the needed height is determined based on a need to reduce cross flow. At block 2812, the example actuator controller circuitry 2612 raises (e.g., via the linear motors 1214) the actuator plate 1116 (with the available nozzle 802 coupled thereto based on the energized electromagnet 1502) to the needed height. Thereafter, control advances to block 2814. Returning to block 2808, if the example height determining circuitry 2610 determines that there are other nozzles 802 already raised from baseline height, the height of the nozzles is already set (e.g., based on a previously adjusted nozzle for a previously addressed (e.g., more critical) hotspot). Accordingly, control advances directly to block 2814.

At block 2814, the example actuator controller circuitry 2612 adjusts the angle of jet vector impingement of available nozzle given the height of the actuator plate. In some examples, this adjustment is made by controlling the associated rotary motor 1123 as discussed above. Thereafter, the example process of FIG. 28 ends and returns to complete the process of FIG. 27.

FIG. 29 is a block diagram of an example programmable circuitry platform 2900 structured to execute and/or instantiate the example machine-readable instructions and/or the example operations of FIGS. 27 and 28 to implement the controller circuitry 2600 of FIG. 26. The programmable circuitry platform 2900 can be, for example, a server, a personal computer, a workstation, a self-learning machine (e.g., a neural network), a mobile device (e.g., a cell phone, a smart phone, a tablet such as an iPad™M), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing and/or electronic device.

The programmable circuitry platform 2900 of the illustrated example includes programmable circuitry 2912. The programmable circuitry 2912 of the illustrated example is hardware. For example, the programmable circuitry 2912 can be implemented by one or more integrated circuits, logic circuits, FPGAs, microprocessors, CPUs, GPUs, DSPs, and/or microcontrollers from any desired family or manufacturer. The programmable circuitry 2912 may be implemented by one or more semiconductor based (e.g., silicon based) devices. In this example, the programmable circuitry 2912 implements the example interface circuitry 2602, the example temperature data analyzing circuitry 2604, the example predictive data analyzing circuitry 2606, the example jet vector determining circuitry 2608, the example height determining circuitry 2610, and the example actuator controller circuitry 2612.

The programmable circuitry 2912 of the illustrated example includes a local memory 2913 (e.g., a cache, registers, etc.). The programmable circuitry 2912 of the illustrated example is in communication with main memory 2914, 2916, which includes a volatile memory 2914 and a non-volatile memory 2916, by a bus 2918. The volatile memory 2914 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 2916 may be implemented by flash memory and/or any other desired type of memory device. Access to the main memory 2914, 2916 of the illustrated example is controlled by a memory controller 2917. In some examples, the memory controller 2917 may be implemented by one or more integrated circuits, logic circuits, microcontrollers from any desired family or manufacturer, or any other type of circuitry to manage the flow of data going to and from the main memory 2914, 2916.

The programmable circuitry platform 2900 of the illustrated example also includes interface circuitry 2920. The interface circuitry 2920 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 2922 are connected to the interface circuitry 2920. The input device(s) 2922 permit(s) a user (e.g., a human user, a machine user, etc.) to enter data and/or commands into the programmable circuitry 2912. The input device(s) 2922 can be implemented by, for example, an audio sensor, a microphone, a camera (still or video), a keyboard, a button, a mouse, a touchscreen, a trackpad, a trackball, an isopoint device, and/or a voice recognition system.

One or more output devices 2924 are also connected to the interface circuitry 2920 of the illustrated example. The output device(s) 2924 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 2920 of the illustrated example, thus, typically includes a graphics driver card, a graphics driver chip, and/or graphics processor circuitry such as a GPU.

The interface circuitry 2920 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 2926. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 2900 of the illustrated example also includes one or more mass storage discs or devices 2928 to store firmware, software, and/or data. Examples of such mass storage discs or devices 2928 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine readable instructions 2932, which may be implemented by the machine readable instructions of FIGS. 27 and 28, may be stored in the mass storage device 2928, in the volatile memory 2914, in the non-volatile memory 2916, and/or on at least one non-transitory computer readable storage medium such as a CD or DVD which may be removable.

FIG. 30 is a block diagram of an example implementation of the programmable circuitry 2912 of FIG. 29. In this example, the programmable circuitry 2912 of FIG. 29 is implemented by a microprocessor 3000. For example, the microprocessor 3000 may be a general-purpose microprocessor (e.g., general-purpose microprocessor circuitry). The microprocessor 3000 executes some or all of the machine-readable instructions of the flowcharts of FIGS. 27 and 28 to effectively instantiate the circuitry of FIG. 26 as logic circuits to perform operations corresponding to those machine readable instructions. In some such examples, the circuitry of FIG. 26 is instantiated by the hardware circuits of the microprocessor 3000 in combination with the machine-readable instructions. For example, the microprocessor 3000 may be implemented by multi-core hardware circuitry such as a CPU, a DSP, a GPU, an XPU, etc. Although it may include any number of example cores 3002 (e.g., 1 core), the microprocessor 3000 of this example is a multi-core semiconductor device including N cores. The cores 3002 of the microprocessor 3000 may operate independently or may cooperate to execute machine readable instructions. For example, machine code corresponding to a firmware program, an embedded software program, or a software program may be executed by one of the cores 3002 or may be executed by multiple ones of the cores 3002 at the same or different times. In some examples, the machine code corresponding to the firmware program, the embedded software program, or the software program is split into threads and executed in parallel by two or more of the cores 3002. The software program may correspond to a portion or all of the machine readable instructions and/or operations represented by the flowcharts of FIGS. 27 and 28.

The cores 3002 may communicate by a first example bus 3004. In some examples, the first bus 3004 may be implemented by a communication bus to effectuate communication associated with one(s) of the cores 3002. For example, the first bus 3004 may be implemented by at least one of an Inter-Integrated Circuit (I2C) bus, a Serial Peripheral Interface (SPI) bus, a PCI bus, or a PCle bus. Additionally or alternatively, the first bus 3004 may be implemented by any other type of computing or electrical bus. The cores 3002 may obtain data, instructions, and/or signals from one or more external devices by example interface circuitry 3006. The cores 3002 may output data, instructions, and/or signals to the one or more external devices by the interface circuitry 3006. Although the cores 3002 of this example include example local memory 3020 (e.g., Level 1 (L1) cache that may be split into an L1 data cache and an L1 instruction cache), the microprocessor 3000 also includes example shared memory 3010 that may be shared by the cores (e.g., Level 2 (L2 cache)) for high-speed access to data and/or instructions. Data and/or instructions may be transferred (e.g., shared) by writing to and/or reading from the shared memory 3010. The local memory 3020 of each of the cores 3002 and the shared memory 3010 may be part of a hierarchy of storage devices including multiple levels of cache memory and the main memory (e.g., the main memory 2914, 2916 of FIG. 29). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 3002 may be referred to as a CPU, DSP, GPU, etc., or any other type of hardware circuitry. Each core 3002 includes control unit circuitry 3014, arithmetic and logic (AL) circuitry (sometimes referred to as an ALU) 3016, a plurality of registers 3018, the local memory 3020, and a second example bus 3022. Other structures may be present. For example, each core 3002 may include vector unit circuitry, single instruction multiple data (SIMD) unit circuitry, load/store unit (LSU) circuitry, branch/jump unit circuitry, floating-point unit (FPU) circuitry, etc. The control unit circuitry 3014 includes semiconductor-based circuits structured to control (e.g., coordinate) data movement within the corresponding core 3002. The AL circuitry 3016 includes semiconductor-based circuits structured to perform one or more mathematic and/or logic operations on the data within the corresponding core 3002. The AL circuitry 3016 of some examples performs integer based operations. In other examples, the AL circuitry 3016 also performs floating-point operations. In yet other examples, the AL circuitry 3016 may include first AL circuitry that performs integer-based operations and second AL circuitry that performs floating-point operations. In some examples, the AL circuitry 3016 may be referred to as an Arithmetic Logic Unit (ALU).

The registers 3018 are semiconductor-based structures to store data and/or instructions such as results of one or more of the operations performed by the AL circuitry 3016 of the corresponding core 3002. For example, the registers 3018 may include vector register(s), SIMD register(s), general-purpose register(s), flag register(s), segment register(s), machine-specific register(s), instruction pointer register(s), control register(s), debug register(s), memory management register(s), machine check register(s), etc. The registers 3018 may be arranged in a bank as shown in FIG. 30. Alternatively, the registers 3018 may be organized in any other arrangement, format, or structure, such as by being distributed throughout the core 3002 to shorten access time. The second bus 3022 may be implemented by at least one of an I2C bus, a SPI bus, a PCI bus, or a PCIe bus.

Each core 3002 and/or, more generally, the microprocessor 3000 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 3000 is a semiconductor device fabricated to include many transistors interconnected to implement the structures described above in one or more integrated circuits (ICs) contained in one or more packages.

The microprocessor 3000 may include and/or cooperate with one or more accelerators (e.g., acceleration circuitry, hardware accelerators, etc.). In some examples, accelerators are implemented by logic circuitry to perform certain tasks more quickly and/or efficiently than can be done by a general-purpose processor. Examples of accelerators include ASICs and FPGAs such as those discussed herein. A GPU, DSP and/or other programmable device can also be an accelerator. Accelerators may be on-board the microprocessor 3000, in the same chip package as the microprocessor 3000 and/or in one or more separate packages from the microprocessor 3000.

FIG. 31 is a block diagram of another example implementation of the programmable circuitry 2912 of FIG. 29. In this example, the programmable circuitry 2912 is implemented by FPGA circuitry 3100. For example, the FPGA circuitry 3100 may be implemented by an FPGA. The FPGA circuitry 3100 can be used, for example, to perform operations that could otherwise be performed by the example microprocessor 3000 of FIG. 30 executing corresponding machine readable instructions. However, once configured, the FPGA circuitry 3100 instantiates the operations and/or functions corresponding to the machine readable instructions in hardware and, thus, can often execute the operations/functions faster than they could be performed by a general-purpose microprocessor executing the corresponding software.

More specifically, in contrast to the microprocessor 3000 of FIG. 30 described above (which is a general purpose device that may be programmed to execute some or all of the machine readable instructions represented by the flowchart(s) of FIGS. 27 and 28 but whose interconnections and logic circuitry are fixed once fabricated), the FPGA circuitry 3100 of the example of FIG. 31 includes interconnections and logic circuitry that may be configured, structured, programmed, and/or interconnected in different ways after fabrication to instantiate, for example, some or all of the operations/functions corresponding to the machine readable instructions represented by the flowchart(s) of FIGS. 27 and 28. In particular, the FPGA circuitry 3100 may be thought of as an array of logic gates, interconnections, and switches. The switches can be programmed to change how the logic gates are interconnected by the interconnections, effectively forming one or more dedicated logic circuits (unless and until the FPGA circuitry 3100 is reprogrammed). The configured logic circuits enable the logic gates to cooperate in different ways to perform different operations on data received by input circuitry. Those operations may correspond to some or all of the instructions (e.g., the software and/or firmware) represented by the flowchart(s) of FIGS. 27 and 28. As such, the FPGA circuitry 3100 may be configured and/or structured to effectively instantiate some or all of the operations/functions corresponding to the machine readable instructions of the flowchart(s) of FIGS. 27 and 28 as dedicated logic circuits to perform the operations/functions corresponding to those software instructions in a dedicated manner analogous to an ASIC. Therefore, the FPGA circuitry 3100 may perform the operations/functions corresponding to the some or all of the machine readable instructions of FIGS. 27 and 28 faster than the general-purpose microprocessor can execute the same.

In the example of FIG. 31, the FPGA circuitry 3100 is configured and/or structured in response to being programmed (and/or reprogrammed one or more times) based on a binary file. In some examples, the binary file may be compiled and/or generated based on instructions in a hardware description language (HDL) such as Lucid, Very High Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 3100 of FIG. 31 may access and/or load the binary file to cause the FPGA circuitry 3100 of FIG. 31 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 3100 of FIG. 31 to cause configuration and/or structuring of the FPGA circuitry 3100 of FIG. 31, or portion(s) thereof.

In some examples, the binary file is compiled, generated, transformed, and/or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, and/or otherwise output from the uniform software platform based on the second instructions. In some examples, the FPGA circuitry 3100 of FIG. 31 may access and/or load the binary file to cause the FPGA circuitry 3100 of FIG. 31 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 3100 of FIG. 31 to cause configuration and/or structuring of the FPGA circuitry 3100 of FIG. 31, or portion(s) thereof.

The FPGA circuitry 3100 of FIG. 31, includes example input/output (I/O) circuitry 3102 to obtain and/or output data to/from example configuration circuitry 3104 and/or external hardware 3106. For example, the configuration circuitry 3104 may be implemented by interface circuitry that may obtain a binary file, which may be implemented by a bit stream, data, and/or machine-readable instructions, to configure the FPGA circuitry 3100, or portion(s) thereof. In some such examples, the configuration circuitry 3104 may obtain the binary file from a user, a machine (e.g., hardware circuitry (e.g., programmable or dedicated circuitry) that may implement an Artificial Intelligence/Machine Learning (AI/ML) model to generate the binary file), etc., and/or any combination(s) thereof). In some examples, the external hardware 3106 may be implemented by external hardware circuitry. For example, the external hardware 3106 may be implemented by the microprocessor 3000 of FIG. 30.

The FPGA circuitry 3100 also includes an array of example logic gate circuitry 3108, a plurality of example configurable interconnections 3110, and example storage circuitry 3112. The logic gate circuitry 3108 and the configurable interconnections 3110 are configurable to instantiate one or more operations/functions that may correspond to at least some of the machine readable instructions of FIGS. 27 and 28 and/or other desired operations. The logic gate circuitry 3108 shown in FIG. 31 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 3108 to enable configuration of the electrical structures and/or the logic gates to form circuits to perform desired operations/functions. The logic gate circuitry 3108 may include other electrical structures such as look-up tables (LUTs), registers (e.g., flip-flops or latches), multiplexers, etc.

The configurable interconnections 3110 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 3108 to program desired logic circuits.

The storage circuitry 3112 of the illustrated example is structured to store result(s) of the one or more of the operations performed by corresponding logic gates. The storage circuitry 3112 may be implemented by registers or the like. In the illustrated example, the storage circuitry 3112 is distributed amongst the logic gate circuitry 3108 to facilitate access and increase execution speed.

The example FPGA circuitry 3100 of FIG. 31 also includes example dedicated operations circuitry 3114. In this example, the dedicated operations circuitry 3114 includes special purpose circuitry 3116 that may be invoked to implement commonly used functions to avoid the need to program those functions in the field. Examples of such special purpose circuitry 3116 include memory (e.g., DRAM) controller circuitry, PCle controller circuitry, clock circuitry, transceiver circuitry, memory, and multiplier-accumulator circuitry. Other types of special purpose circuitry may be present. In some examples, the FPGA circuitry 3100 may also include example general purpose programmable circuitry 3118 such as an example CPU 3120 and/or an example DSP 3122. Other general purpose programmable circuitry 3118 may additionally or alternatively be present such as a GPU, an XPU, etc., that can be programmed to perform other operations.

Although FIGS. 30 and 31 illustrate two example implementations of the programmable circuitry 2912 of FIG. 29, many other approaches are contemplated. For example, FPGA circuitry may include an on-board CPU, such as one or more of the example CPU 3120 of FIG. 30. Therefore, the programmable circuitry 2912 of FIG. 29 may additionally be implemented by combining at least the example microprocessor 3000 of FIG. 30 and the example FPGA circuitry 3100 of FIG. 31. In some such hybrid examples, one or more cores 3002 of FIG. 30 may execute a first portion of the machine readable instructions represented by the flowchart(s) of FIGS. 27 and 28 to perform first operation(s)/function(s), the FPGA circuitry 3100 of FIG. 31 may be configured and/or structured to perform second operation(s)/function(s) corresponding to a second portion of the machine readable instructions represented by the flowcharts of FIGS. 27 and 28, and/or an ASIC may be configured and/or structured to perform third operation(s)/function(s) corresponding to a third portion of the machine readable instructions represented by the flowcharts of FIGS. 27 and 28.

It should be understood that some or all of the circuitry of FIG. 26 may, thus, be instantiated at the same or different times. For example, same and/or different portion(s) of the microprocessor 3000 of FIG. 30 may be programmed to execute portion(s) of machine-readable instructions at the same and/or different times. In some examples, same and/or different portion(s) of the FPGA circuitry 3100 of FIG. 31 may be configured and/or structured to perform operations/functions corresponding to portion(s) of machine-readable instructions at the same and/or different times.

In some examples, some or all of the circuitry of FIG. 26 may be instantiated, for example, in one or more threads executing concurrently and/or in series. For example, the microprocessor 3000 of FIG. 30 may execute machine readable instructions in one or more threads executing concurrently and/or in series. In some examples, the FPGA circuitry 3100 of FIG. 31 may be configured and/or structured to carry out operations/functions concurrently and/or in series. Moreover, in some examples, some or all of the circuitry of FIG. 26 may be implemented within one or more virtual machines and/or containers executing on the microprocessor 3000 of FIG. 30.

In some examples, the programmable circuitry 2912 of FIG. 29 may be in one or more packages. For example, the microprocessor 3000 of FIG. 30 and/or the FPGA circuitry 3100 of FIG. 31 may be in one or more packages. In some examples, an XPU may be implemented by the programmable circuitry 2912 of FIG. 29, which may be in one or more packages. For example, the XPU may include a CPU (e.g., the microprocessor 3000 of FIG. 30, the CPU 3120 of FIG. 31, etc.) in one package, a DSP (e.g., the DSP 3122 of FIG. 31) in another package, a GPU in yet another package, and an FPGA (e.g., the FPGA circuitry 3100 of FIG. 31) in still yet another package.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time +1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that enabling dynamic adjustments to the position and/or orientation of nozzles in a jet impingement cooling system to target specific locations on an IC package to be cooled. By targeting hotspots on an IC package, more efficient cooling can be achieved. Further, in some examples, the dynamic adjustments are based on predictions of future hotspots based on imminent workloads and scheduled tasks to be performed by the IC package. By adjusting the nozzles to begin cooling specific locations expected to increase in temperature once a schedule task is initiated, the specific locations can be preemptively cooled to reduce any rise in temperature and potentially avoid actual hotspots from developing in the first place. This can increase the reliability and longevity of a given IC package and/or enable an IC package to be operated at more extreme powers without concern for exceeding the thermal design limits. Furthermore, this can improve the overall efficiency of data centers by allowing servers to operate at a higher utilization rate than would be possible using known cooling systems due to risks of the servers overheating. Disclosed systems, apparatus, articles of manufacture, and methods are accordingly directed to one or more improvement(s) in the operation of a machine such as a computer or other electronic and/or mechanical device.

Further examples and combinations thereof include the following:

Example 1 includes an apparatus comprising an array of nozzles to direct a cooling fluid toward an integrated circuit package, the array of nozzles including a first nozzle and a second nozzle, and a plate to carry the array of nozzles, the first nozzle selectively moveable relative to the integrated circuit package and relative to the second nozzle, movement of the first nozzle relative to the integrated circuit package and relative to the second nozzle including translational movement.

Example 2 includes the apparatus of example 1, wherein the plate is a first plate, the apparatus further including a second plate that is selectively moveable relative to the integrated circuit package and relative to the first plate, the second nozzle to move with the second plate and relative to the first nozzle.

Example 3 includes the apparatus of example 2, further including an electromagnet to hold the first nozzle in fixed spatial relationship to the second plate when the electromagnet is in a first energy state, the second plate to move with respect to the first nozzle when the electromagnet is in a second energy state different than the first energy state.

Example 4 includes the apparatus of example 3, wherein the electromagnet is a first electromagnet, the apparatus further including a second electromagnet to selectively hold the second nozzle in fixed spatial relationship to the second plate depending on whether the second electromagnet is in the first energy state or the second energy state, the second electromagnet controllable independent of the first electromagnet.

Example 5 includes the apparatus of any one of examples 3 or 4, further including an armature surrounding and supporting the first nozzle, the armature to move relative to the second plate in response to the electromagnet switching between the first energy state and the second energy state.

Example 6 includes the apparatus of any one of examples 2-5, further including a linear actuator to selectively move the second plate to different distances from the integrated circuit package.

Example 7 includes the apparatus of any one of examples 2-6, wherein the second plate is selectively moveable between a first position and a second position, the first position to be closer to the integrated circuit package than the second position is to the integrated circuit package, the first position spaced apart from the second position by at least 5 millimeters.

Example 8 includes the apparatus of any one of examples 2-7, further including programmable circuitry to: determine locations of hotspots on the integrated circuit package, and cause, based on the locations of the hotspots, adjustments to at least one of (a) a distance of the second plate from to the integrated circuit package or (b) angles of impingement of ones of the nozzles relative to the integrated circuit package.

Example 9 includes the apparatus of any one of examples 1-8, wherein the movement of the first nozzle relative to the integrated circuit package and relative to the second nozzle includes rotational movement.

Example 10 includes the apparatus of example 9, further including a nozzle casing to support the first nozzle, the first nozzle capable of rotating about multiple axes relative to the nozzle casing via a gimballed connection, the first nozzle coupled to the plate via the nozzle casing.

Example 11 includes the apparatus of example 10, wherein the nozzle casing includes an opening that extends through a wall of the casing, and the apparatus further includes a rotary motor, and a connecting rod coupling the rotary motor to the nozzle, the connecting rod connected to the nozzle through the opening in the nozzle casing.

Example 12 includes the apparatus of example 11, wherein the opening defines an elongate track that extends around a portion of the nozzle, the apparatus further including a roller bearing to move along the track, the roller bearing to support an anchor between the connecting rod and the nozzle.

Example 13 includes the apparatus of example 12, wherein rotation of the rotary motor is to cause a change in location of the roller bearing along the track, the change in location of the roller bearing to cause a change in an angle of impingement of the nozzle relative to the integrated circuit package.

Example 14 includes the apparatus of any one of examples 12 or 13, wherein a first point along the track is a first distance away from an end of the nozzle casing, and a second point along the track is a second distance away from the end of the nozzle casing, the first distance different than the second distance.

Example 15 includes the apparatus of example 14, wherein the track is an undulating track with multiple peaks and troughs distributed about the nozzle, the first point associated with a first one of the peaks and the second point associated with a first one of the troughs.

Example 16 includes the apparatus of any one of examples 14 or 15, wherein the rotary motor is mounted to the plate, and the connecting rod is a telescopic rod to enable the connecting rod to change length based on whether the roller bearing is at the first point along the track or at the second point along the track.

Example 17 includes an apparatus comprising a nozzle to direct a jet stream of cooling fluid toward an integrated circuit package, a nozzle casing to carry the nozzle, the nozzle rotatable relative to the nozzle casing via a gimballed connection to adjust an angle of impingement of the jet stream on the integrated circuit package, and a plate to support the nozzle casing, the nozzle casing moveable relative to the plate between a first position and a second position, the first position to be closer to the integrated circuit package than the second position is to the integrated circuit package.

Example 18 includes the apparatus of example 17, wherein the gimballed connection is defined by a ball head on the nozzle within a spherical cavity in the nozzle casing, the ball head defining an inlet for the nozzle.

Example 19 includes the apparatus of any one of examples 17 or 18, wherein the angle of impingement of the jet stream is adjusted by a motor rotating the nozzle relative to the nozzle casing.

Example 20 includes an apparatus comprising a plate to support an array of nozzle above an integrated circuit package, the array of nozzles to direct cooling fluid towards the integrated circuit package, and a nozzle seat assembly to couple a first nozzle of the array of nozzles to the plate, the nozzle seat assembly selectively moveable relative to the plate towards and away from the integrated circuit package, the first nozzle selectively rotatable relative to the nozzle seat assembly.

Example 21 includes the apparatus of example 20, wherein the nozzle seat assembly includes an armature, and the apparatus further includes an electromagnet, the nozzle seat assembly to move relative to the plate based on an energy state of the electromagnet.

Example 22 includes an apparatus comprising interface circuitry, machine readable instructions, and at least one programmable circuit to at least one of instantiate or execute the machine readable instructions to determine a location of a hotspot on an integrated circuit package, determine an angle of a nozzle in a jet impingement cooling system to produce a jet stream of fluid that targets the hotspot, and cause an actuator to adjust a position of the nozzle according to the determined angle.

Example 23 includes the apparatus of example 22, wherein the hotspot is a current hotspot determined based on temperature data from temperature sensors associated with the integrated circuit package.

Example 24 includes the apparatus of any one of examples 22 or 23, wherein the hotspot is a future hotspot determined based on predictive data, the predictive data including at least one of imminent workloads or scheduled tasks to be performed by the integrated circuit package.

Example 25 includes the apparatus of any one of examples 22-24, wherein the hotspot is a first hotspot, and the nozzle is a first nozzle, one or more of the at least one programmable circuit to determine locations of a plurality of hotspots on the integrated circuit package, the plurality of hotspots including the first hotspot, order the plurality of hotspots based on a criticality of different ones of the plurality of hotspots, and determine positions of an array of nozzles based on the order of the plurality of hotspots, the array of nozzles including the first nozzle.

Example 26 includes the apparatus of any one of examples 22-25, wherein one or more of the at least one programmable circuit is to cause an electromagnet to be activated in response to a determination that a height of the nozzle over the integrated circuit package is to be adjusted, the electromagnet on a plate, the plate adjacent the nozzle.

Example 27 includes the apparatus of example 26, wherein one or more of the at least one programmable circuit is to cause a motor to move the plate relative to the integrated circuit package.

Example 28 includes the apparatus of any one of examples 22-27, wherein the determined angle is a first angle associated with a first position of the nozzle, and the actuator is a rotary motor, one or more of the at least one programmable circuit to cause the rotary motor to rotate, rotation of the rotary motor to cause the nozzle to rotate from a second position to the first position, the second position associated with a second angle different than the first angle.

Example 29 includes a non-transitory machine readable storage medium comprising instructions to at least one cause programmable circuit to at least determine a location of a hotspot on an integrated circuit package, determine an angle of a nozzle in a jet impingement cooling system to produce a jet stream of fluid that targets the hotspot, and cause an actuator to adjust a position of the nozzle according to the determined angle.

Example 30 includes the non-transitory machine readable storage medium of example 29, wherein the hotspot is a current hotspot determined based on temperature data from temperature sensors associated with the integrated circuit package.

Example 31 includes the non-transitory machine readable storage medium of any one of examples 29 or 30, wherein the hotspot is a future hotspot determined based on predictive data, the predictive data including at least one of imminent workloads or scheduled tasks to be performed by the integrated circuit package.

Example 32 includes the non-transitory machine readable storage medium of any one of examples 29-31, wherein the hotspot is a first hotspot, and the nozzle is a first nozzle, the instructions to cause one or more of the at least one programmable circuit to determine locations of a plurality of hotspots on the integrated circuit package, the plurality of hotspots including the first hotspot, order the plurality of hotspots based on a criticality of different ones of the plurality of hotspots, and determine positions of an array of nozzles based on the order of the plurality of hotspots, the array of nozzles including the first nozzle.

Example 33 includes the non-transitory machine readable storage medium of any one of examples 29-32, wherein the instructions cause one or more of the at least one programmable circuit to cause an electromagnet to be activated in response to a determination that a height of the nozzle over the integrated circuit package is to be adjusted, the electromagnet on a plate, the plate adjacent the nozzle.

Example 34 includes the non-transitory machine readable storage medium of example 33, wherein the instructions cause one or more of the at least one programmable circuit to cause a motor to move the plate relative to the integrated circuit package.

Example 35 includes the non-transitory machine readable storage medium of any one of examples 29-35, wherein the determined angle is a first angle associated with a first position of the nozzle, and the actuator is a rotary motor, the instructions to cause one or more of the at least one programmable circuit to cause the rotary motor to rotate, rotation of the rotary motor to cause the nozzle to rotate from a second position to the first position, the second position associated with a second angle different than the first angle.

Example 36 includes a method comprising determining, by at least one programmable circuit executing instructions, a location of a hotspot on an integrated circuit package, determining, by one or more of the at least one programmable circuit executing the instructions, an angle of a nozzle in a jet impingement cooling system to produce a jet stream of fluid that targets the hotspot, and causing an actuator to adjust a position of the nozzle according to the determined angle.

Example 37 includes the method of example 36, wherein the hotspot is a current hotspot determined based on temperature data from temperature sensors associated with the integrated circuit package.

Example 38 includes the method of any one of examples 36 or 37, wherein the hotspot is a future hotspot determined based on predictive data, the predictive data including at least one of imminent workloads or scheduled tasks to be performed by the integrated circuit package.

Example 39 includes the method of any one of examples 36-38, wherein the hotspot is a first hotspot, and the nozzle is a first nozzle, the method further including determining locations of a plurality of hotspots on the integrated circuit package, the plurality of hotspots including of the first hotspot, ordering the plurality of hotspots based on a criticality of different ones of the plurality of hotspots, and determining positions of an array of nozzles based on the order of the plurality of hotspots, the array of nozzles including the first nozzle.

Example 40 includes the method of any one of examples 36-39, further including causing an electromagnet to be activated in response to a determination that a height of the nozzle over the integrated circuit package is to be adjusted, the electromagnet on a plate, the plate adjacent the nozzle.

Example 41 includes the method of example 40, further including causing a motor to move the plate relative to the integrated circuit package.

Example 42 includes the method of any one of examples 36-41, wherein the determined angle is a first angle associated with a first position of the nozzle, and the actuator is a rotary motor, the method further including causing the rotary motor to rotate, rotation of the rotary motor to cause the nozzle to rotate from a second position to the first position, the second position associated with a second angle different than the first angle.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

1. An apparatus comprising:
an array of nozzles to direct a cooling fluid toward an integrated circuit package, the array of nozzles including a first nozzle and a second nozzle; and
a plate to carry the array of nozzles, the first nozzle selectively moveable relative to the integrated circuit package and relative to the second nozzle, movement of the first nozzle relative to the integrated circuit package and relative to the second nozzle including translational movement.

2. The apparatus of claim 1, wherein the plate is a first plate, the apparatus further including a second plate that is selectively moveable relative to the integrated circuit package and relative to the first plate, the second nozzle to move with the second plate and relative to the first nozzle.

3. The apparatus of claim 2, further including an electromagnet to hold the first nozzle in fixed spatial relationship to the second plate when the electromagnet is in a first energy state, the second plate to move with respect to the first nozzle when the electromagnet is in a second energy state different than the first energy state.

4. The apparatus of claim 3, wherein the electromagnet is a first electromagnet, the apparatus further including a second electromagnet to selectively hold the second nozzle in fixed spatial relationship to the second plate depending on whether the second electromagnet is in the first energy state or the second energy state, the second electromagnet controllable independent of the first electromagnet.

5. The apparatus of claim 3, further including an armature surrounding and supporting the first nozzle, the armature to move relative to the second plate in response to the electromagnet switching between the first energy state and the second energy state.

6. The apparatus of claim 2, further including a linear actuator to selectively move the second plate to different distances from the integrated circuit package.

7. The apparatus of claim 2, wherein the second plate is selectively moveable between a first position and a second position, the first position to be closer to the integrated circuit package than the second position is to the integrated circuit package, the first position spaced apart from the second position by at least 5 millimeters.

8. The apparatus of claim 2, further including programmable circuitry to:
determine locations of hotspots on the integrated circuit package; and
cause, based on the locations of the hotspots, adjustments to at least one of (a) a distance of the second plate from to the integrated circuit package or (b) angles of impingement of ones of the nozzles relative to the integrated circuit package.

9. The apparatus of claim 1, wherein the movement of the first nozzle relative to the integrated circuit package and relative to the second nozzle includes rotational movement.

10. The apparatus of claim 9, further including a nozzle casing to support the first nozzle, the first nozzle capable of rotating about multiple axes relative to the nozzle casing via a gimballed connection, the first nozzle coupled to the plate via the nozzle casing.

11. The apparatus of claim 10, wherein the nozzle casing includes an opening that extends through a wall of the casing, and the apparatus further includes:
a rotary motor; and
a connecting rod coupling the rotary motor to the nozzle, the connecting rod connected to the nozzle through the opening in the nozzle casing.

12. The apparatus of claim 11, wherein the opening defines an elongate track that extends around a portion of the nozzle, the apparatus further including a roller bearing to move along the track, the roller bearing to support an anchor between the connecting rod and the nozzle.

13. The apparatus of claim 12, wherein rotation of the rotary motor is to cause a change in location of the roller bearing along the track, the change in location of the roller bearing to cause a change in an angle of impingement of the nozzle relative to the integrated circuit package.

14. The apparatus of claim 12, wherein a first point along the track is a first distance away from an end of the nozzle casing, and a second point along the track is a second distance away from the end of the nozzle casing, the first distance different than the second distance.

15. The apparatus of claim 14, wherein the track is an undulating track with multiple peaks and troughs distributed about the nozzle, the first point associated with a first one of the peaks and the second point associated with a first one of the troughs.

16. (canceled)

17. An apparatus comprising:
a nozzle to direct a jet stream of cooling fluid toward an integrated circuit package;
a nozzle casing to carry the nozzle, the nozzle rotatable relative to the nozzle casing via a gimballed connection to adjust an angle of impingement of the jet stream on the integrated circuit package; and
a plate to support the nozzle casing, the nozzle casing moveable relative to the plate between a first position and a second position, the first position to be closer to the integrated circuit package than the second position is to the integrated circuit package.

18. The apparatus of claim 17, wherein the gimballed connection is defined by a ball head on the nozzle within a spherical cavity in the nozzle casing, the ball head defining an inlet for the nozzle.

19. The apparatus of claim 17, wherein the angle of impingement of the jet stream is adjusted by a motor rotating the nozzle relative to the nozzle casing.

20. An apparatus comprising:
a plate to support an array of nozzle above an integrated circuit package, the array of nozzles to direct cooling fluid towards the integrated circuit package; and
a nozzle seat assembly to couple a first nozzle of the array of nozzles to the plate, the nozzle seat assembly selectively moveable relative to the plate towards and away from the integrated circuit package, the first nozzle selectively rotatable relative to the nozzle seat assembly.

21. The apparatus of claim 20, wherein the nozzle seat assembly includes an armature, and the apparatus further includes an electromagnet, the nozzle seat assembly to move relative to the plate based on an energy state of the electromagnet.

22-42. (canceled)
